(19) United States
(12) Patent Application Publication
(10) Pub. No.: US 2025/0300340 A1
(43) Pub. Date: Sep. 25, 2025

(54) RESONATOR, DIELECTRIC CHARACTERISTIC MEASUREMENT SYSTEM, AND DIELECTRIC CHARACTERISTIC MEASURING METHOD

(71) Applicant: Murata Manufacturing Co., Ltd., Nagaokakyo-shi (JP)

(72) Inventor: Osamu SHIBATA, Nagaokakyo-shi, Kyoto (JP)

(73) Assignee: Murata Manufacturing Co., Ltd., Nagaokakyo-shi (JP)

(21) Appl. No.: 19/227,859

(22) Filed: Jun. 4, 2025

Related U.S. Application Data
(63) Continuation of application No. PCT/JP2023/041484, filed on Nov. 17, 2023.

(30) Foreign Application Priority Data
Dec. 9, 2022 (JP) 2022-196980

(51) Int. Cl. H01P 7/10; G01R 27/26; H01P 3/12

(52) U.S. Cl. CPC H01P 7/10; G01R 27/2664; H01P 3/122

(57) ABSTRACT

A resonator includes a first waveguide and a second waveguide having plate shapes and opposed to in a first direction, and a multilayer body provided in a space between them. The multilayer body includes a circular conductor foil sandwiched between two dielectric layers having a plate shape. A connecting portion is provided at one end of the propagation path of the waveguide. A communication hole to connect the propagation path with a space between the first waveguide and the second waveguide is provided on the other waveguide side of the one waveguide. The multilayer body is provided between the first waveguide and the second waveguide. In plan view in the first direction, the communication hole is located inside an inner wall of the propagation path and overlaps the propagation path and a center of the circular conductor foil.

### CROSS-REFERENCE TO RELATED APPLICATIONS

The present application is a continuation of PCT/JP2023/041484, filed Nov. 17, 2023, which claims priority to Japanese patent application JP 2022-196980, filed Dec. 9, 2022, and the entire contents of each of which being incorporated herein by reference.

### TECHNICAL FIELD

The present disclosure relates to a resonator, a dielectric characteristic measurement system, and a dielectric characteristic measuring method.

### BACKGROUND ART

As disclosed in Non Patent Document 1, a resonator has been used as an instrument to measure dielectric characteristics of a dielectric body. The resonator is configured to carry out measurement while sandwiching, between a pair of conductor plates, dielectric layers that interpose a circular disk resonator plate. In a case of carrying out the measurement at a frequency equal to or below 110 GHz, input and output of an electromagnetic wave to and from the resonator is carried out by way of a coaxial line connected to a conductive member. Non Patent Document 2 discloses a resonator which can measure dielectric characteristics at a frequency band defining 170 GHz as an upper limit by setting an inside diameter of a coaxial line to 0.8 mm.

### CITATION LIST

### Non Patent Documents

Non Patent Document 1: IEC, Measurement of the complex permittivity for low-loss dielectric substrates balanced-type circular disk resonator method, IEC 63185, 2020.12.08.
Non Patent Document 2: IEEE Transactions on Instrumentation and Measurement, (US), 2019, Vol. 68, No. 6, p. 1796-1805

### SUMMARY

### Technical Problems

However, Non Patent Document 1 does not define a measuring method at a frequency higher than 110 GHz and the measuring method at a high frequency band has not been established as standards. Meanwhile, since the resonator according to Non Patent Document 2 measures the dielectric characteristics at a high frequency band, the inside diameter of the coaxial line needs to be reduced. In this case, a coupling portion between a waveguide and the coaxial line and a coupling portion between the coaxial line and the conductive member may have complicated structures. Accordingly, the coaxial line may be difficult to manufacture, or a strength of the resonator may be insufficient.

The present disclosure has been made in view of the aforementioned and other problems, and is directed to providing a resonator, a dielectric characteristic measurement system, and a dielectric characteristic measuring method, which are capable of measuring dielectric characteristics at a high frequency band with a simple structure.

### Solutions to Problems

A resonator according to an aspect of the present disclosure includes a first waveguide having a plate shape and provided with a first propagation path; a second waveguide having a plate shape and provided with a second propagation path, the second waveguide being opposed to the first waveguide in a first direction; and a multilayer body including a circular conductor foil and two dielectric layers having a plate shape and sandwiching the circular conductor foil in the first direction. The first waveguide has a first connecting portion at one end of the first propagation path. The second waveguide has a second connecting portion at one end of the second propagation path. The first waveguide has, on the second waveguide side, a first communication hole to connect the first propagation path with a space between the first waveguide and the second waveguide. The second waveguide has, on the first waveguide side, a second communication hole to connect the second propagation path with the space between the first waveguide and the second waveguide. The multilayer body is provided in the space between the first waveguide and the second waveguide. In plan view in the first direction, the first communication hole overlaps the first propagation path and an external form of the first communication hole is located inside an inner wall of the first propagation path. In plan view in the first direction, the second communication hole overlaps the second propagation path and an external form of the second communication hole is located inside an inner wall of the second propagation path. In plan view in the first direction, the first communication hole and the second communication hole overlap a circular center of the circular conductor foil.

A dielectric characteristic measurement system according to an aspect of the present disclosure includes the above resonator, a transmission unit that transmits an input wave to the resonator, a reception unit that receives an output wave from the resonator, and an information processing unit that calculates dielectric characteristics of the dielectric layers.

A dielectric characteristic measuring method according to an aspect of the present disclosure includes transmitting an input wave to the above resonator, receiving an output wave from the above resonator, and calculating dielectric characteristics of the above dielectric layers.

According to the present disclosure, the dielectric characteristics can be measured at a high frequency band with a simple structure.

### BRIEF DESCRIPTION OF DRAWINGS

FIG. 1 is a schematic diagram showing a dielectric characteristic measurement system according to a first embodiment.

FIG. 2 is a perspective view of a resonator according to the first embodiment.

FIG. 3 is a cross-sectional view taken along line III-III in FIG. 2.

FIG. 4A is a plan view of a first waveguide according to the first embodiment.

FIG. 4B is a plan view of a second waveguide according to the first embodiment.

FIG. 5 is a block diagram showing an information processing apparatus according to the first embodiment.

FIG. 6 is a perspective view showing a resonator according to a second embodiment.

FIG. 7 is a cross-sectional view taken along line VII-VII in FIG. 6.

FIG. 8A is a plan view of a first waveguide according to the second embodiment.

FIG. 8B is a plan view of a second waveguide according to the second embodiment.

FIG. 9 is a perspective view of a resonator according to a third embodiment.

FIG. 10 is a cross-sectional view taken along line X-X in FIG. 9.

FIG. 11A is a plan view showing a first waveguide according to the third embodiment.

FIG. 11B is a plan view showing a second waveguide according to the third embodiment.

FIG. 12 is a perspective view of a resonator according to a fourth embodiment.

FIG. 13 is a cross-sectional view taken along line XIII-XIII in FIG. 12.

FIG. 14A is a plan view showing a first waveguide according to the fourth embodiment.

FIG. 14B is a plan view showing a second waveguide according to the fourth embodiment.

FIG. 15 is a diagram depicting a graph showing a result of measurement of a reflection coefficient and a bandpass coefficient according to Example 1.

FIG. 16 is a diagram depicting a graph showing a result of simulation of a reflection coefficient and a bandpass coefficient according to Example 2.

FIG. 17 is a diagram depicting a graph showing a result of simulation of a reflection coefficient and a bandpass coefficient according to Example 3.

FIG. 18 is a diagram depicting a graph showing a result of simulation of a reflection coefficient and a bandpass coefficient according to Example 4.

FIG. 19 is a diagram depicting a graph showing results of calculation of dielectric characteristics according to Example 5, Comparative Example 1, and Comparative Example 2.

FIG. 20 is a diagram depicting a graph showing results of simulation according to Example 6, Comparative Example 3, and Comparative Example 4.

FIG. 21 is a perspective view of a resonator according to a first modified example.

FIG. 22A is a cross-sectional view taken along line XXIIA-XXIIA in FIG. 21.

FIG. 22B is a cross-sectional view taken along line XXIIB-XXIIB in FIG. 21.

FIG. 23A is a plan view showing a first waveguide according to the first modified example.

FIG. 23B is a plan view showing a second waveguide according to the first modified example.

### DESCRIPTION OF EMBODIMENTS

Embodiments of the present disclosure will be described below. It is to be noted that these embodiments are not intended to limit the present disclosure. The respective embodiments are merely exemplary, and configurations shown in different embodiments can be partially replaced or combined.

### First Embodiment

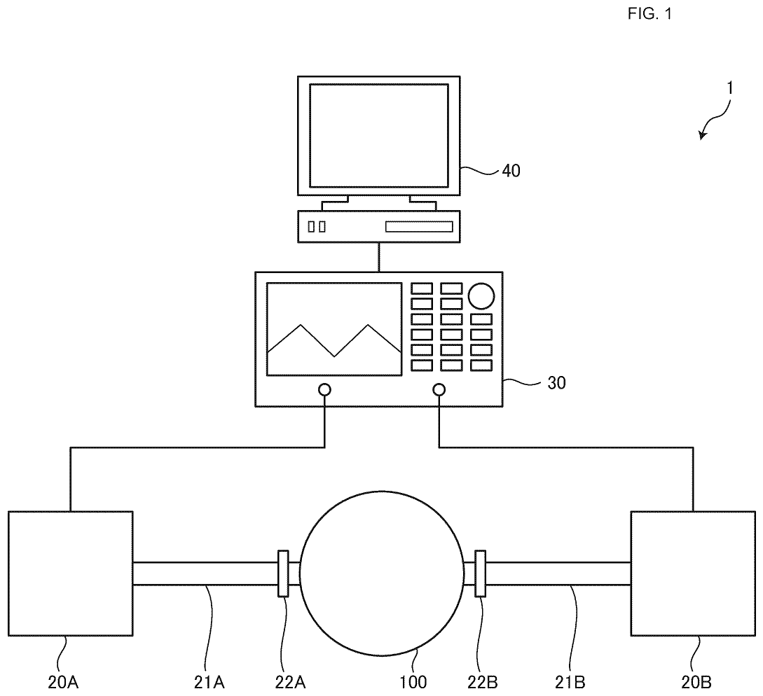

FIG. 1 is a schematic diagram showing a dielectric characteristic measurement system according to a first embodiment. A dielectric characteristic measurement system 1 shown in FIG. 1 is a system that measures dielectric characteristics of a dielectric body. As shown in FIG. 1, the dielectric characteristic measurement system 1 according to the first embodiment includes a resonator 100, converters 20A and 20B, a measurement apparatus 30, and an information processing apparatus 40.

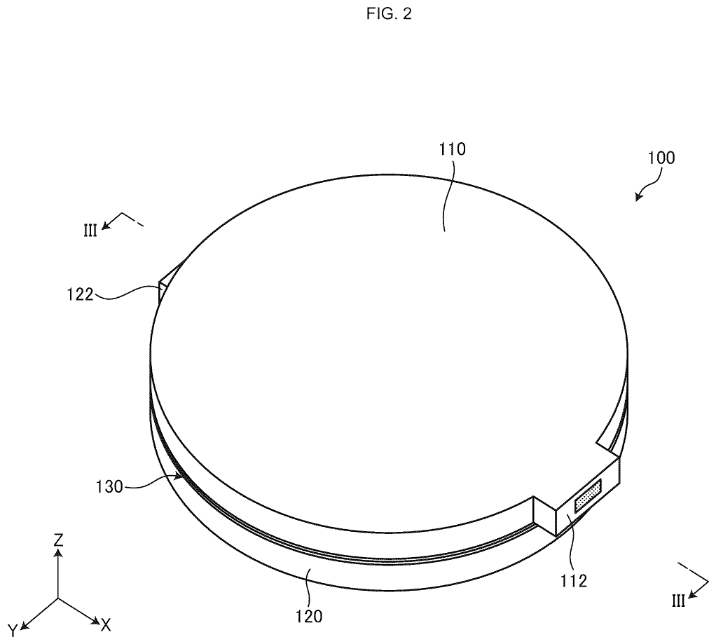

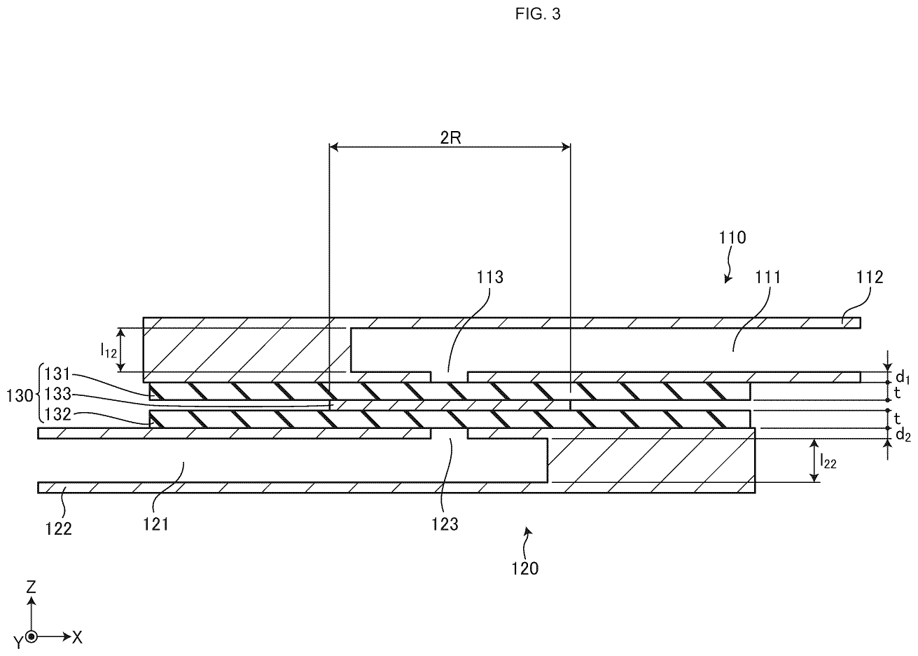

FIG. 2 is a perspective view of the resonator 100 according to the first embodiment. FIG. 3 is a cross-sectional view taken along line III-III in FIG. 2. The resonator 100 is a balanced-type circular disk resonator that excites and outputs a TM₀ₘ₀ mode (m is a natural number) in response to input of an electromagnetic wave. As shown in FIG. 2 and FIG. 3, the resonator 100 includes a first waveguide 110, a second waveguide 120, and a multilayer body 130. The resonator 100 adopts a multilayer structure in which the multilayer body 130 is sandwiched between the first waveguide 110 and the second waveguide 120. In other words, the multilayer body 130 is disposed in a space between the first waveguide 110 and the second waveguide 120. The multilayer body 130 includes dielectric layers 131 and 132, and a circular conductor foil 133. Here, the first waveguide 110 and the second waveguide 120 serve as waveguides and conductor plates of the resonator. In other words, the first waveguide 110 and the second waveguide 120 are capable of propagating the electromagnetic wave while serving as the waveguides and of confining an electromagnetic field in the space between the first waveguide 110 and the second waveguide 120 while serving as the conductor plates of the resonator.

The dielectric characteristic measurement system 1 measures dielectric characteristics of the dielectric layers 131 and 132 by evaluating the resonator 100. To be more precise, the dielectric characteristic measurement system 1 measures the dielectric characteristics of the dielectric layers 131 and 132 by inputting the electromagnetic wave from the measurement apparatus 30 to the resonator 100, causing the resonator 100 to excite the TM₀ₘ₀ mode, and measuring the TM₀ₘ₀ mode output from the resonator 100 by using the measurement apparatus 30. Here, frequency characteristics of the TM₀ₘ₀ mode excited by the resonator 100 depend on the dielectric characteristics of the dielectric layers 131 and 132 and on a radius of the circular conductor foil 133. Accordingly, the dielectric characteristic measurement system 1 can measure the dielectric characteristics on a desired dielectric body by causing the information processing apparatus 40 to process the frequency characteristics obtained by the measurement apparatus 30. Here, in the dielectric characteristic measurement system 1, the dielectric layers 131 and 132 can be taken out of the resonator 100 and replaced with dielectric layers made of dielectric bodies of different materials, thicknesses, and so forth. In this way, the dielectric characteristic measurement system 1 can also measure dielectric characteristics concerning such different dielectric bodies.

In the following description, a direction of lamination of the first waveguide 110, the second waveguide 120, and the multilayer body 130 will be referred to as z direction. Meanwhile, the electromagnetic wave input to the resonator 100 is referred to as an input wave and the electromagnetic wave output from the resonator 100 is referred to as an output wave as appropriate. Here, in the measurement of the dielectric characteristics using the dielectric characteristic measurement system 1 according to the first embodiment, the input wave is swept in a predetermined frequency band. Herein, a swept frequency band is referred to as a measurement frequency band, a lower limit of the measurement frequency band is referred to as a start frequency, and an upper limit of the measurement frequency band is referred to as a stop frequency as appropriate.

### (First Waveguide)

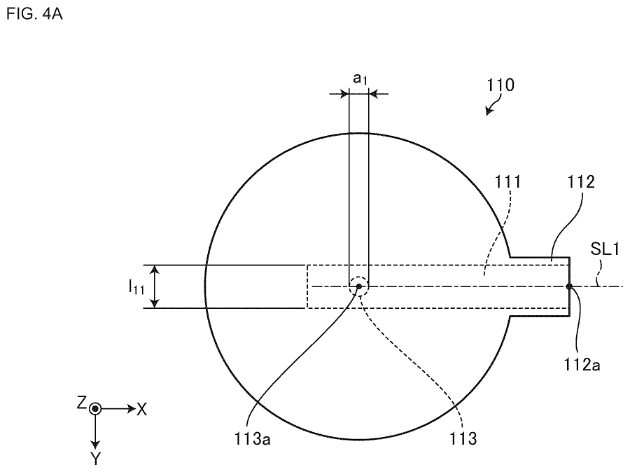

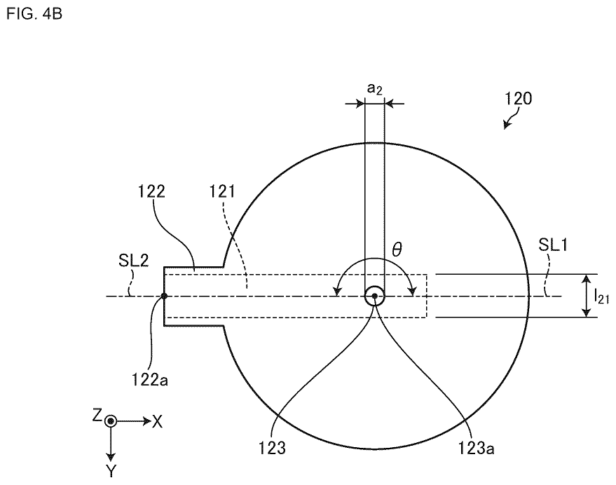

FIG. 4A is a plan view of the first waveguide according to the first embodiment. The first waveguide 110 serves as the waveguide that propagates the input wave to the resonator 100 and as the conductor plate of the resonator that cuts off a leakage of an excited wave from the multilayer body 130. As shown in FIG. 3 and FIG. 4A, the first waveguide 110 has a plate shape. Although the first waveguide 110 has a disc shape in the first embodiment, the shape is not limited thereto and may be any other plate shape, e.g., a square. The first waveguide 110 is made of a conductor such as copper with known conductivity. Now, a structure of the first waveguide 110 according to the first embodiment will be described below in detail.

The first waveguide 110 includes a first propagation path 111. The first propagation path 111 is a space in the first waveguide 110, which propagates the input wave. Thus, the first propagation path 111 is a space provided to the first waveguide 110. As shown in FIG. 4A, in the first embodiment, an inner wall of the first propagation path 111 has a length in a direction perpendicular to the z direction. The inner wall of the first propagation path 111 is formed into a rectangular shape in plan view in the z direction. In other words, the first propagation path 111 has a columnar shape having the length in the direction perpendicular to the z direction.

A cross-sectional shape of the inner wall of the first propagation path 111, i.e., a cross-section of the inner wall of the first propagation path 111 in a direction along a direction perpendicular to a direction of propagation of the input wave is a rectangle. In other words, the first waveguide 110 is a square waveguide. Here, a state of being a rectangle includes not only a perfect rectangle but also a substantial rectangle having four sides such as a rectangle with rounded vertices. In this way, a plane of polarization of the first propagation path 111 can appropriately be controlled.

In the following description, a cutoff frequency represents the lowest value of a frequency of an electromagnetic wave that can be propagated on the waveguide. In the waveguide, the electromagnetic wave equal to or above the cutoff frequency is not cut off and is therefore propagated, whereas the electromagnetic wave below the cutoff frequency is cut off and is not therefore propagated. A basic mode represents a mode having the lowest cutoff frequency. Meanwhile, a secondary mode represents a mode having the next lowest cutoff frequency after that in the basic mode.

The cutoff frequency in the basic mode of the first waveguide 110 is equal to or below the start frequency. By setting this range, the first waveguide 110 can propagate the electromagnetic wave equal to or above the start frequency, and can therefore measure the dielectric characteristics throughout the measurement frequency band. On the other hand, when the cutoff frequency is greater than the start frequency, the first waveguide 110 cuts off an electromagnetic wave below the cutoff frequency in the basic mode and cannot propagate the electromagnetic wave. Accordingly, the dielectric characteristics in the measurement frequency band may be inaccurately measured.

The cutoff frequency in the secondary mode of the first waveguide 110 is larger than the stop frequency. Accordingly, the first waveguide 110 cuts off a mode (hereinafter a high-order mode) other than the basic mode at a frequency equal to or below the stop frequency, so that propagation of the high-order mode can be suppressed and the dielectric characteristics can be appropriately measured throughout the measurement frequency band. On the other hand, when the cutoff frequency in the secondary mode of the first waveguide 110 is smaller than the stop frequency, the first waveguide 110 also propagates an electromagnetic wave in the high-order mode equal to or above the cutoff frequency in the secondary mode. Accordingly, the dielectric characteristics in the measurement frequency band may be inaccurately measured.

As shown in FIG. 3 and FIG. 4A, in the first embodiment, the cross-sectional shape of the inner wall of the first propagation path 111 is the rectangle having long sides and short sides. A length l₁₁ of the long side of the rectangle, e.g., along a y direction, is twice as large as a length l₁₂ of the short side thereof, e.g., along the z direction. Here, in the example in FIG. 3 and FIG. 4A, the long side extends in a direction parallel to the direction perpendicular to the z direction and the short side extends in a direction parallel to the z direction. However, this configuration is merely an example. Now, a detailed description will be given below of dimensions of the shape regarding the cross-section of the inner wall of the first propagation path 111 with which the cutoff frequency in the basic mode of the first waveguide 110 becomes equal to or below a start frequency fₗ and the cutoff frequency in the secondary mode of the first waveguide 110 becomes larger than a stop frequency fₕ.

In the case where the cross-sectional shape of the inner wall of the first propagation path 111 is the rectangle, a cutoff frequency f_{c} of the first waveguide 110 is expressed by the following formula (1). Here, in the formula (1), c denotes the light speed in a free space, n denotes the circumference ratio, and p and q each denote an integer equal to or above 0. In the following explanation, a TE mode corresponding to p and q will be expressed as a TE_{pq} mode. Meanwhile, a free space wavelength of an electromagnetic wave having the cutoff frequency, i.e., a value obtained by dividing the light speed c in the free space by the cutoff frequency will be referred to as a cutoff wavelength.

$$[ Math . 1 ]$$

$${f}_{c} = \frac{c}{2 π} \sqrt{{( \frac{p π}{{l}_{11}} )}^{2} + {( \frac{q π}{{l}_{12}} )}^{2}} \qquad ( 1 )$$

In the first embodiment, the basic mode is a TE₁₀ mode since the length l₁₁ of the long side is larger than the length l₁₂ of the short side. A cutoff frequency f_{c1} in the TE₁₀ mode is expressed by the following formula (2). In the first embodiment, the secondary mode is a TE₂₀ mode since the length l₁₁ of the long side is twice as large as the length l₁₂ of the short side. In this case, a cutoff frequency f_{c2} in the TE₂₀ mode is expressed by the following formula (3).

$$[ Math . 2 ]$$

$${f}_{C 1} = \frac{c}{2 {l}_{11}} \qquad ( 2 )$$

$$[ Math . 3 ]$$

$${f}_{C 2} = \frac{c}{{l}_{11}} \qquad ( 3 )$$

Accordingly, as shown in the following formula (4), the cutoff frequency f_{c1} in the basic mode of the first waveguide 110 can be set equal to or below the start frequency fₗ and the cutoff frequency f_{c2} in the secondary mode of the first waveguide 110 can be set larger than the stop frequency fₕ by setting the length l₁₁ of the long side equal to or above a half of a free space wavelength at the start frequency fₗ and below a free space wavelength at the stop frequency fₕ. In this way, the first waveguide 110 can propagate the input wave throughout the measurement frequency band while cutting off the higher order modes and can therefore appropriately measure the dielectric characteristics.

$$[ Math . 4 ]$$

$$\frac{c}{2 {f}_{l}} \leq {l}_{11} < \frac{c}{{f}_{h}} \qquad ( 4 )$$

In the first embodiment, the start frequency fₗ is 110 GHz while the stop frequency fₕ is 170 GHz. In this case, the cross-sectional shape of the inner wall of the first propagation path 111 is the rectangle having the length l₁₁ of the long side of 1.651 mm and the length l₁₂ of the short side of 0.8255 mm, for example. Accordingly, the length l₁₁ of the long side is twice as large as the length l₁₂ of the short side and the length l₁₁ of the long side satisfies the formula (4). As a consequence, the first waveguide 110 can propagate the input wave throughout the measurement frequency band equal to or above 110 GHz and equal to or below 170 GHz while cutting off the higher-order modes, and can appropriately measure the dielectric characteristics.

A first connecting portion 112 is provided at one end of the first propagation path 111. The first connecting portion 112 is a portion for connecting the first waveguide 110 to an external device. As shown in FIG. 2 and FIG. 3, in the first embodiment, the first connecting portion 112 is provided at a side surface of the first waveguide 110. The first connecting portion 112 is formed into a frame-like member having a cavity that penetrates in a direction perpendicular to the z direction. The shape of the cavity of the first connecting portion 112 is the same shape as the cross-sectional shape of the inner wall of the first propagation path 111. Although a structure of a connecting portion to a waveguide 21A to be described later is omitted in FIG. 2, the first connecting portion 112 has a structure such as a flange that is connectable to the waveguide 21A to be described later with a flange 22A interposed therebetween. In this way, the first connecting portion 112 can propagate the input wave that is input to the resonator 100 to the first waveguide 110.

In the following description, a direction parallel to a straight line SL1 that connects a circular center 113a of a first communication hole 113 to a center 112a of the cavity of the first connecting portion 112 is referred to as x direction while a direction perpendicular to the x direction and the z direction is referred to as y direction in some cases. Here, the center 112a of the first connecting portion 112 represents a geometrical center of gravity of a region occupied by the cavity in plan view in a direction of penetration of the first connecting portion 112 by the cavity.

The first communication hole 113 is provided to the first waveguide 110. As shown in FIG. 3, the first communication hole 113 is a hole that connects the space between the first propagation path 111 and the second waveguide 120. In other words, the first communication hole 113 is a hole made that penetrates in the z direction from the inner wall on the second waveguide 120 side of the first propagation path 111. In plan view in the z direction of the first communication hole 113, the first communication hole 113 is provided at a position to overlap the first propagation path 111 and its external form is located inside the inner wall of the first propagation path 111. In other words, the first communication hole 113 is provided at the inner wall on the second waveguide 120 side of the first propagation path 111 and does not to come into contact with an inner wall other than the inner wall on the second waveguide 120 side of the first propagation path 111. In plan view in the z direction, the first communication hole 113 is provided at a position to overlap a circular center of the circular conductor foil 133 to be described later. This makes it possible to cause the dielectric layers 131 and 132 in contact with the circular conductor foil 133 to excite an electric field in the TM₀ₘ₀ mode in such a way as to arrange anti-nodes and nodes of a standing wave concentrically about the circular center of the circular conductor foil 133 in plan view from the z direction.

The first communication hole 113 assists in causing the electromagnetic wave propagated on the first propagation path 111 to transition to the multilayer body 130 as an evanescent wave. To be more precise, a wave (the evanescent wave) to be propagated in such a way as to flows from a reflected surface toward the multilayer body 130 is generated around the first communication hole 113 of the first propagation path 111 when the input wave is totally reflected from the inner wall. In this instance, the generated evanescent wave is caused to transition to the multilayer body 130 at a sufficient intensity as a consequence of providing the first communication hole 113.

A length d₁ of the inner wall of the first communication hole 113 in the z direction is equal to or below 0.4 times of the free space wavelength at the stop frequency fₕ. Here, the length d₁ of the inner wall of the first communication hole 113 in the z direction represents a thickness of the inner wall of the first propagation path 111 around the first communication hole 113 shown in FIG. 3. By setting this range, the first communication hole 113 can cause the evanescent wave from the first propagation path 111 to transition to the multilayer body 130 at a sufficient intensity. On the other hand, the length d₁ is greater than 0.4 times of the free space wavelength at the stop frequency fₕ, the evanescent wave is attenuated by the inner wall of the first propagation path 111. Accordingly, the intensity of the evanescent wave to transition to the multilayer body 130 may be insufficient.

The length d₁ of the inner wall of the first communication hole 113 in the z direction is larger than a skin thickness dₛ₁ of a material of the first waveguide 110 at the start frequency fₗ. The skin thickness represents a depth from a surface of a range where a skin effect develops significantly. To be more precise, the skin thickness represents a distance at which the magnitude of an electric current flowing in the conductor becomes 1/e times as large as an electric current flowing on a surface of a conductive wire due to the skin effect. The skin thickness dₛ₁ is expressed by the following formula (5). Here, in the formula (5), n denotes the circumference ratio, fₗ denotes the start frequency, μᵣ₁ denotes relative magnetic permeability of the material of the first waveguide 110, μ₀ denotes a magnetic constant of the free space, and σ₁ denotes conductivity of the material of the first waveguide 110. By setting this range, leakage of the input wave from the inner wall of the first propagation path 111 due to the skin effect throughout the measurement frequency band may be suppressed. On the other hand, when the length d₁ is smaller than the skin thickness dₛ₁, the input wave from the inner wall of the first propagation path 111 at a portion of the measurement frequency band due to the skin effect may leak.

$$[ Math . 5 ]$$

$${d}_{s 1} = \frac{1}{\sqrt{π {f}_{l} {μ}_{r 1} {μ}_{0} {σ}_{1}}} \qquad ( 5 )$$

In the first embodiment, the material of the first waveguide 110 is copper and the start frequency fₗ is 110 GHz. Accordingly, the skin thickness dₛ₁ is 0.625 μm. Therefore, the length d₁ only needs to be set larger than 0.625 μm in this case. In this way, leakage of the input wave from the inner wall of the first propagation path 111 due to the skin effect throughout the measurement frequency band may be suppressed. In the meantime, the length d₁ may be set to a substantially larger value than the skin thickness dₛ₁ such as equal to or above 10 μm. In this way, the leakage of the input wave from the inner wall of the first propagation path 111 due to the skin effect throughout the measurement frequency band may be further suppressed.

As described above, the length d₁ of the inner wall of the first communication hole 113 in the z direction is equal to or below 0.4 times of the free space wavelength at the stop frequency fₕ and is larger than the skin thickness dₛ₁ of the material of the first waveguide 110 at the start frequency fₗ. By setting this range, the first communication hole 113 can cause the evanescent wave from the first propagation path 111 to be transmitted to the multilayer body 130 at a sufficient intensity and leakage of the input wave from the inner wall of the first propagation path 111 due to the skin effect throughout the measurement frequency band may be suppressed.

As shown in FIG. 4A, in the first embodiment, the first communication hole 113 is circular in plan view in the z direction. In the following description, a diameter of a circle of a region occupied by the first communication hole 113 in plan view in the z direction will be referred to as a diameter a₁ of the first communication hole 113. A range of the diameter a₁ of the first communication hole 113 will be described below.

In the first embodiment, the diameter a₁ of the first communication hole 113 is equal to or above 0.2 times of the free space wavelength at the start frequency fₗ. By setting this range, the evanescent wave having a sufficient intensity for excitation to transition to the multilayer body 130 may be generated. On the other hand, when the diameter a₁ is less than 0.2 times of the free space wavelength at the start frequency fₗ, the intensity of the evanescent wave to be transmitted to the multilayer body 130 is reduced and an influence of noise is relatively increased. As a result, the dielectric characteristics may not be accurately measured.

In the first embodiment, the diameter a₁ of the first communication hole 113 is equal to or below 0.4 times of the free space wavelength at the stop frequency fₕ. By setting this range, the cutoff frequency in the basic mode in the case of regarding the first communication hole 113 as a circular waveguide can be made larger than the stop frequency fₕ. Accordingly, the first communication hole 113 can suppress propagation of the basic mode of the first waveguide 110 to the multilayer body 130 as the circular waveguide throughout the measurement frequency band, so that only the evanescent wave is transmitted to the multilayer body 130 and the dielectric characteristics can be accurately measured. On the other hand, when the diameter a₁ is greater than 0.4 times of the free space wavelength at the stop frequency fₕ, the first communication hole 113 propagates the input wave as the waveguide and an excitation mode as the waveguide is observed by a measuring instrument. Accordingly, the measurement of the dielectric characteristics may be inaccurate.

As described above, the dielectric characteristics can be accurately measured by setting the diameter a₁ of the first communication hole 113 within a range of the following formula (6).

$$[ Math . 6 ]$$

$$0.2 \times \frac{c}{{f}_{1}} \leq {a}_{1} \leq 0.4 \times \frac{c}{{f}_{h}} \qquad ( 6 )$$

### (Second Waveguide)

FIG. 4B is a plan view of the second waveguide according to the first embodiment. The second waveguide 120 serves as the waveguide that propagates the output wave from the resonator 100 and as the conductor plate of the resonator that cuts off the excited wave from the multilayer body 130. The second waveguide 120 has a plate shape. Although the second waveguide 120 has a disc shape in the first embodiment as shown in FIG. 3 and FIG. 4B, the shape is not limited thereto and may be a plate shape such as a square. The second waveguide 120 is made of a conductor such as copper with known conductivity. Now, a structure of the second waveguide 120 according to the first embodiment will be described below in detail.

The second waveguide 120 includes a second propagation path 121. The second propagation path 121 is a space in the second waveguide 120 that propagates the input wave. Thus, the second propagation path 121 is a space provided to the second waveguide 120. As shown in FIG. 4B, in the first embodiment, an inner wall of the second propagation path 121 has a length in the direction perpendicular to the z direction. The inner wall of the second propagation path 121 is formed into a rectangular shape in plan view in the z direction. In other words, the second propagation path 121 has a columnar shape having the length in the direction perpendicular to the z direction.

A cross-sectional shape of the inner wall of the second propagation path 121, i.e., a cross-section of the inner wall of the second propagation path 121 in a direction along a direction perpendicular to a direction of propagation of the input wave is a rectangle. In other words, the second waveguide 120 is a square waveguide. Here, a state of being a rectangle includes not only a perfect rectangle but also a substantial rectangle having four sides such as a rectangle with rounded vertices. In this way, a plane of polarization of the second propagation path 121 can appropriately be controlled.

The cutoff frequency in the basic mode of the second waveguide 120 is equal to or below the start frequency fₗ. By setting this range, the second waveguide 120 can propagate an electromagnetic wave equal to or above the start frequency fₗ, and can therefore measure the dielectric characteristics throughout the measurement frequency band. On the other hand, when the cutoff frequency in the basic mode of the second waveguide 120 is greater than the start frequency fₗ, the second waveguide 120 cuts off an electromagnetic wave below the cutoff frequency in the basic mode and cannot propagate the electromagnetic wave. Accordingly, the dielectric characteristics in the measurement frequency band may be measured inaccurately.

The cutoff frequency in the secondary mode of the second waveguide 120 is larger than the stop frequency fₕ. Accordingly, the second waveguide 120 cuts off the high-order mode at a frequency equal to or below the stop frequency, so that propagation of the high-order mode can be suppressed and the dielectric characteristics can appropriately be measured throughout the measurement frequency band. On the other hand, when the cutoff frequency in the secondary mode of the second waveguide 120 is smaller than the stop frequency fₕ., the second waveguide 120 also propagates an electromagnetic wave in the high-order mode equal to or above the cutoff frequency in the secondary mode. Accordingly, the dielectric characteristics in the measurement frequency band may be measured inaccurately.

As shown in FIG. 3 and FIG. 4B, in the first embodiment, the cross-sectional shape of the inner wall of the second waveguide 120 is the rectangle having long sides and short sides. A length l₂₁ of the long side of the rectangle is designed to be twice as large as a length l₂₂ of the short side thereof. Here, in the example in FIG. 3 and FIG. 4B, the long side extends in the direction parallel to the direction perpendicular to the z direction and the short side extends in the direction parallel to the z direction. However, this configuration is merely an example. In this case, as shown in the following formula (7), the cutoff frequency in the basic mode of the second waveguide 120 can be set equal to or below the start frequency fₗ and the cutoff frequency in the secondary mode of the second waveguide 120 can be set larger than the stop frequency fₕ by setting the length l₂₁ of the long side equal to or above a half of the free space wavelength at the start frequency fₗ and below the free space wavelength at the stop frequency fₕ as with the first waveguide 110. In this way, the second waveguide 120 can propagate the output wave throughout the measurement frequency band while cutting off the high-order mode, and can therefore appropriately measure the dielectric characteristics.

$$[ Math . 7 ]$$

$$\frac{c}{2 {f}_{l}} \leq {l}_{21} < \frac{c}{{f}_{h}} \qquad ( 7 )$$

In the first embodiment, the start frequency fₗ is 110 GHz while the stop frequency fₕ is 170 GHz. In this case, the cross-sectional shape of the inner wall of the second propagation path 121 has the length 121 of the long side of 1.651 mm and the length 122 of the short side of 0.8255 mm, for example. Accordingly, the length 121 of the long side is twice as large as the length 122 of the short side and the length 121 of the long side satisfies the formula (7). As a consequence, the second waveguide 120 can propagate the output wave throughout the measurement frequency band equal to or above 110 GHz and equal to or below 170 GHz while cutting off the high-order mode. Thus, the dielectric characteristics may be appropriately measured.

A second connecting portion 122 is provided at one end of the second propagation path 121. The second connecting portion 122 is a portion for connecting the second waveguide 120 to an external device. As shown in FIG. 2 and FIG. 3, in the first embodiment, the second connecting portion 122 is provided at a side surface of the second waveguide 120. The second connecting portion 122 is formed into a frame-like member having a cavity that penetrates in the direction perpendicular to the z direction. The shape of the cavity of the second connecting portion 122 is the same shape as the cross-sectional shape of the inner wall of the second propagation path 121. Although a structure of a connecting portion to a waveguide 21B to be described later is omitted in FIG. 2, the second connecting portion 122 has a structure such as a flange that is connectable to the waveguide 21B to be described later with a flange 22B interposed therebetween. In this way, the second connecting portion 122 can propagate the output wave that is outputted from the resonator 100 from the second waveguide 120.

As shown in FIG. 4B, in the first embodiment, a straight line SL2 that connects a circular center 123a of a second communication hole 123 to a center 122a of the cavity of the second connecting portion 122 is parallel to the x direction. Here, the center 122a of the cavity of the second connecting portion 122 represents a geometrical center of gravity of a region occupied by the cavity in plan view in a direction of penetration of the second connecting portion 122 by the cavity. An angle θ formed between the straight line SL1 that passes through the circular center 113a of the first communication hole 113 as well as the center 112a of the cavity of the first connecting portion 112 and the straight line SL2 that passes through circular center 123a of the second communication hole 123 as well as the center 122a of the cavity of the second connecting portion 122 is 180°. In other words, the second connecting portion 122 is provided at a position opposed to the first connecting portion 112 in plan view in the z direction.

The second communication hole 123 is provided to the second waveguide 120. As shown in FIG. 3, the second communication hole 123 is a hole that connects the space between the second propagation path 121 and the second waveguide 120. In other words, the second communication hole 123 is a hole made in such a way as to penetrate in the z direction from the inner wall on the second waveguide 120 side of the second propagation path 121. In plan view of in the z direction, the second communication hole 123 is provided at a position to overlap the second propagation path 121 and its external form is located inside the inner wall of the second propagation path 121. In other words, the second communication hole 123 is provided at the inner wall on the second waveguide 120 side of the second propagation path 121 and does not to come into contact with an inner wall other than the inner wall on the second waveguide 120 side of the second propagation path 121. In plan view in the z direction, the second communication hole 123 is provided at a position to overlap a circular center of the circular conductor foil 133 to be described later. Thus, the TM₀ₘ₀ mode that is excited at the circular center of the circular conductor foil 133 is appropriately transmitted to the second propagation path 121.

The second communication hole 123 assists in causing the electromagnetic wave propagated on the multilayer body 130 to be transmitted to the second propagation path 121 as an evanescent wave. To be more precise, an evanescent wave from a reflected surface toward the second propagation path 121 is generated around the second communication hole 123 of the second waveguide 120 when the excited wave from the multilayer body is totally reflected from an outer wall of the second waveguide 120. In this instance, the generated evanescent wave is transmitted to the second propagation path 121 at a sufficient intensity by providing the second communication hole 123.

In the first embodiment, a length d₂ of the inner wall of the second communication hole 123 in the z direction is equal to or below 0.4 times of the free space wavelength at the stop frequency fₕ. Here, the length d₂ of the inner wall of the second communication hole 123 in the z direction represents a thickness of the inner wall of the second propagation path 121 around the second communication hole 123 shown in FIG. 3. By setting this range, the second communication hole 123 can cause the evanescent wave from the multilayer body 130 to be transmitted to the second propagation path 121 at a sufficient intensity. On the other hand, when a range outside this range is set, the evanescent wave is attenuated by the inner wall of the second propagation path 121. Accordingly, the intensity of the evanescent wave to transition to the second propagation path 121 may be insufficient.

The length d₂ of the inner wall of the second communication hole 123 in the z direction is larger than a skin thickness dₛ₂ of a material of the second waveguide 120 at the start frequency fₗ. The skin thickness represents the depth from the surface of the range where the skin effect develops significantly. To be more precise, the skin thickness represents the distance at which the magnitude of the electric current flowing in the conductor becomes 1/e times as large as the electric current flowing on the surface of the conductive wire due to the skin effect. The skin thickness dₛ₂ is expressed by the following formula (8). Here, in the formula (8), n denotes the circumference ratio, fₗ denotes the start frequency, μᵣ₂ denotes relative magnetic permeability of the material of the second waveguide 120, μ₀ denotes the magnetic constant of the free space, and σ₂ denotes conductivity of the material of the second waveguide 120. By setting this range, leakage of the input wave from the inner wall of the second propagation path 121 due to the skin effect throughout the measurement frequency band may be suppressed. On the other hand, when a range outside this range is set, the input wave may leak from the inner wall of the second propagation path 121 at a portion of the measurement frequency band due to the skin effect.

$$[ Math . 8 ]$$

$${d}_{s 2} = \frac{1}{\sqrt{π {f}_{l} {μ}_{r 2} {μ}_{0} {σ}_{2}}} \qquad ( 8 )$$

In the first embodiment, the material of the second waveguide 120 is copper and the start frequency fₗ is 110 GHz. Accordingly, the skin thickness dₛ₂ is 0.625 μm. Therefore, the length d₁ only needs to be set larger than 0.625 μm in this case. In this way, the leakage of the output wave from the inner wall of the second propagation path 121 due to the skin effect throughout the measurement frequency band may be suppressed. In the meantime, the length d₂ may be set to a substantially larger value than the skin thickness dₛ₂ such as equal to or above 10 μm. In this way, leakage of the output wave from the inner wall of the second propagation path 121 due to the skin effect throughout the measurement frequency band maybe further suppressed.

As described above, the length d₂ of the inner wall of the second communication hole 123 in the z direction is equal to or below 0.4 times of the free space wavelength at the stop frequency fₕ and is larger than the skin thickness dₛ₂ of the material of the second waveguide 120 at the start frequency fₗ. By setting this range, the second communication hole 123 can cause the evanescent wave from the multilayer body 130 to be transmitted to the second propagation path 121 at a sufficient intensity, and to suppress the leakage of the output wave from the inner wall of the second propagation path 121 due to the skin effect throughout the measurement frequency band.

As shown in FIG. 4B, in the first embodiment, the second communication hole 123 is circular in plan view in the z direction. In the following description, a diameter of a circle of a region occupied by the second communication hole 123 in plan view in the z direction will be explained as a diameter a₂ of the second communication hole 123. A range of the diameter a₂ of the second communication hole 123 will be described below.

In the first embodiment, the diameter a₂ of the second communication hole 123 is equal to or above 0.2 times of the free space wavelength at the start frequency fₗ. By setting this range, the evanescent wave having a sufficient intensity may be transmitted to the second propagation path 121. On the other hand, when the diameter a₂ is less than 0.2 times of the free space wavelength at the start frequency fₗ, the intensity of the evanescent wave transmitted to the second propagation path 121 is reduced and an influence of noise is relatively increased. As a result, the dielectric characteristics may not be accurately measured.

In the first embodiment, the diameter a₂ of the second communication hole 123 is equal to or below 0.4 times of the free space wavelength at the stop frequency fₕ. By setting this range, the cutoff frequency in the basic mode in the case of regarding the second communication hole 123 as the circular waveguide can be made larger than the stop frequency fₕ. Accordingly, the second communication hole 123 can cause only the evanescent wave to be transmitted to the second propagation path 121, thereby accurately measuring the dielectric characteristics. On the other hand, when the diameter a₂ is greater than 0.4 times of the free space wavelength at the stop frequency fₕ, the second communication hole 123 propagates the electromagnetic wave in the waveguide and the excitation mode as the waveguide is observed by the measuring instrument. Accordingly, the measurement of the dielectric characteristics may be inaccurate.

As described above, the dielectric characteristics can be accurately measured by setting the diameter a₂ of the second communication hole 123 within a range of the following formula (9). In the first embodiment, the diameter a₁ of the first communication hole 113 is equal to the diameter a₂ of the second communication hole 123. In the following description, the diameters of the first communication hole 113 and the second communication hole 123 may be denoted by a as appropriate.

$$[ Math . 9 ]$$

$$0.2 \times \frac{c}{{f}_{l}} \leq {a}_{2} \leq 0.4 \times \frac{c}{{f}_{h}} \qquad ( 9 )$$

The multilayer body 130 is provided in the space in the z direction between the first waveguide 110 and the second waveguide 120. As shown in FIG. 3, the multilayer body 130 is a multilayer body in which the circular conductor foil 133 is sandwiched between the two dielectric layers 131 and 132 in the z direction. The multilayer body 130 receives the input wave transitioning from the first waveguide 110 and selectively excites the TM₀ₘ₀ mode at the circular center of the circular conductor foil 133 by electric field coupling. The excited electromagnetic wave in the TM₀ₘ₀ mode is transmitted to the second waveguide 120 as the output wave. In this way, the intensity of the output wave is increased at the frequency in the TM₀ₘ₀ mode excited by the multilayer body 130. A resonant frequency depends on the dielectric characteristics of the dielectric layers 131 and 132 and on a radius R of the circular conductor foil 133. In the following description, the TM₀ₘ₀ mode excited by the multilayer body 130 may be explained as a resonant wave and a frequency of the resonant wave may be explained as the resonant frequency as appropriate.

The dielectric layers 131 and 132 are layers made of dielectric bodies. The dielectric layers 131 and 132 are targets of measurement for the dielectric characteristics of the dielectric characteristic measurement system 1. The dielectric layers 131 and 132 are each a circular disk having a thickness in a first direction, and have the same shape. In the example of FIG. 2, the dielectric layers 131 and 132 are provided such that circular centers thereof overlap each other in plan view in the z direction. The dielectric layers 131 and 132 are made of a material targeted for measurement of the dielectric characteristics, and are made of an insulating material such as a ceramic, glass, or an organic resin. The dielectric layers 131 and 132 may be made of a material having relative permittivity equal to or below about 10. The dielectric characteristics are appropriately measured in this case. Note that the shapes of the dielectric layers 131 and 132 are not limited to the circular disk shape as long as the shapes overlap the conductor foil 133 in plan view in the z direction. In the first embodiment, the thicknesses of the dielectric layers 131 and 132 are equal. In the following description, the thicknesses of the dielectric layers 131 and 132 may be referred as t as appropriate.

The conductor foil 133 is a circular conductive foil having a thickness in the z direction. The conductor foil 133 is made of a conductive body with known conductivity, and is made of copper, for example. The conductor foil 133 is provided between the dielectric layer 131 and the dielectric layer 132 in the z direction, and is provided in such a way as to overlap the dielectric layer 131 and the dielectric layer 132 in plan view in the z direction. In the following description, the radius of the circular conductor foil 133 may be explained as R as appropriate. In FIG. 3, a diameter of the circular conductor foil is 2R, which is twice as large as the radius R.

Note that the resonator according to the first embodiment is not limited to the above-described resonator 100. For example, the measurement frequency band is not limited to the band equal to or above 110 GHz and equal to or below 170 GHz, and may be a frequency band higher than this band. In this case as well, measurement of the dielectric characteristics may be realized by forming the first waveguide 110 and the second waveguide 120 into the above-described structures in response to the start frequency and the stop frequency of the higher frequency band.

As described above, the resonator 100 according to the first embodiment includes the first waveguide 110 having the plate shape and provided with the first propagation path 111, the second waveguide 120 having the plate shape and provided with the second propagation path 121, the second waveguide 120 being opposed to the first waveguide 110 in the first direction (the z direction), and the multilayer body 130 including the conductor foil 133 and the two dielectric layers 131 and 132 that have a plate shape and sandwich the conductor foil 133 in the first direction. The first waveguide 110 has the first connecting portion 112 at one end of the first propagation path 111. The second waveguide 120 has the second connecting portion 122 at one end of the second propagation path 121. The first waveguide 110 has, on the second waveguide 120 side, the first communication hole 113 to connect the first propagation path 111 with the space between the first waveguide 110 and the second waveguide 120. The second waveguide 120 has, on the first waveguide 110 side, the second communication hole 123 to connect the second propagation path 121 with the space between the first waveguide 110 and the second waveguide 120. The multilayer body 130 is provided in the space between the first waveguide 110 and the second waveguide 120. In plan view in the first direction, the first communication hole 113 overlaps the first propagation path 111 and its external form is located inside the inner wall of the first propagation path 111. In plan view in the first direction, the second communication hole 123 overlaps the second propagation path 121 and its external form is located inside the inner wall of the second propagation path 121. In plan view in the first direction, the first communication hole 113 and the second communication hole 123 overlap the center of the conductor foil 133.

Thus, the resonator 100 can realize transmission lines for the input wave and the output wave without using a coaxial line. Therefore, according to the resonator 100 of the first embodiment, the dielectric characteristics can be measured with a simple structure in the high frequency band where a diameter of a transmission line needs to be reduced. As a consequence, by using the resonator 100 according to the first embodiment, a dielectric characteristic measurement apparatus compatible with the high frequency band can be provided with higher measurement accuracy, less expensive, and easier to manufacture.

When the cross-sectional shape of the inner wall of the first propagation path 111 is a rectangle and the cross-sectional shape of the inner wall of the second propagation path 121 is a rectangle, the planes of polarization in the first propagation path 111 and the second propagation path 121 may be properly controlled.

The converter 20A is a device to convert the electromagnetic wave from a low frequency to a high frequency. The converter 20A is connected to the measurement apparatus 30 and converts a low-frequency input wave transmittable by the measurement apparatus 30 to a high-frequency input wave to be inputted to the resonator 100. The converter 20A transmits a converted transmission wave to the resonator 100 with the waveguide 21A interposed therebetween.

The waveguide 21A is a waveguide to connect the converter 20B to the first connecting portion 112 of the resonator 100. The waveguide 21A includes the flange 22A to be connected to the first connecting portion 112 of the resonator 100. The cross-sectional shape of the inner wall of the waveguide 21A is the same as the shape of the first waveguide 110, i.e., in the first embodiment, the waveguide 21A is a square waveguide.

The converter 20B is a device to convert the electromagnetic wave from a low frequency to a high frequency. The converter 20B is connected to the measurement apparatus 30 and converts a high-frequency output wave output from the resonator 100 by way of the waveguide 21B to a low-frequency output wave to be receivable by the measurement apparatus 30. The converter 20B transmits a converted transmission wave to the measurement apparatus 30.

The waveguide 21B is a waveguide to connect the converter 20B to the second connecting portion 122 of the resonator 100. The waveguide 21B includes the flange 22B to be connected to the first connecting portion 112 of the resonator 100. The cross-sectional shape of the inner wall of the waveguide 21B is the same as the shape of the first waveguide 110, i.e., in the first embodiment, the waveguide 21B is a square waveguide.

The measurement apparatus 30 is an apparatus that performs transmission and reception of measurement waves to and from the resonator 100. The measurement apparatus 30 is an apparatus serving as a transmission unit to transmit the input wave to the resonator 100 and as a reception unit to receive the output wave from the resonator 100, which is a vector network analyzer, for example. The measurement apparatus 30 sweeps a frequency band corresponding to the measurement frequency band and transmits the input wave to the resonator 100. The measurement apparatus 30 receives the output wave from the resonator 100 simultaneously with the transmission of the input wave. Thus, the measurement apparatus 30 measures S parameters of a circuit that involves the resonator 100 as a measurement target, and transmits values of the S parameters corresponding to the frequency of the input wave to the information processing apparatus 40.

The S parameters (scattering parameters) are also referred to as scattering matrices, which are parameters to express bandpass and reflection power characteristics of a circuit network. The S parameters include a reflection coefficient |S₁₁| and a bandpass coefficient |S₂₁|. Here, the reflection coefficient |S₁₁| and the bandpass coefficient |S₂₁| are absolute values. The reflection coefficient |S₁₁| is a parameter indicating an amplitude ratio between the input wave and the output wave. The bandpass coefficient |S₂₁| is a parameter indicated in the amplitude ratio between the input wave and the output wave. Accordingly, peaks in a positive direction indicating resonant waves appear in a graph showing the bandpass coefficient |S₂₁| with respect to the frequency of the input wave. The resonant frequency and a 3-dB band width can be specified by analyzing the peaks of the resonant waves. Therefore, the bandpass coefficient |S₂₁| can also be regarded as a parameter that indicates the dielectric characteristics of the dielectric layers 131 and 132.

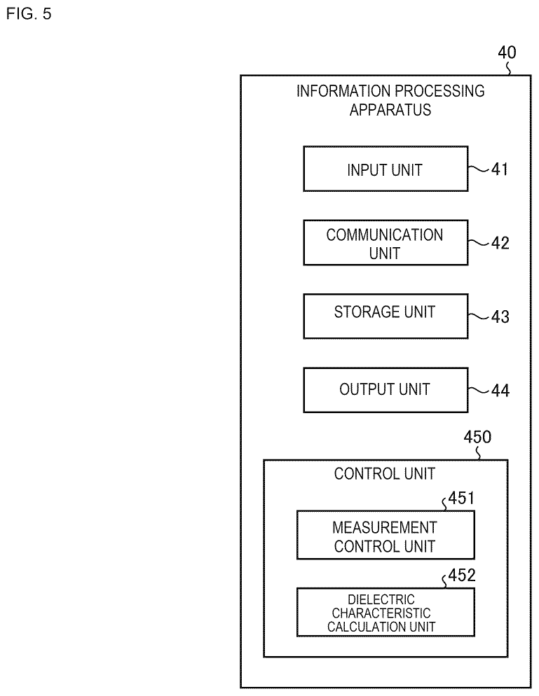

FIG. 5 is a block diagram showing the information processing apparatus according to the first embodiment. The information processing apparatus 40 is an information processing unit to receive information concerning the measurement from the measurement apparatus 30 and to calculate the dielectric characteristics based on the received information. The information processing apparatus 40 is a computer that includes a control unit 450 provided with an operating circuit such as a CPU (central processing unit), and a storage unit 43. The information processing apparatus 40 executes processing by causing the control unit 450 to read a program (software) from the storage unit 43 and to execute the program. As shown in FIG. 5, the information processing apparatus 40 includes an input unit 41, a communication unit 42, the storage unit 43, an output unit 44, and the control unit 450. As used herein, “unit” refers to circuitry that may be configured via the execution of computer readable instructions.

The input unit 41 accepts input to the information processing apparatus 40. The input unit 41 is realized by an input device such as a keyboard, a mouse, and a touch panel.

The communication unit 42 is a communication module that performs communication with an external apparatus such as the measurement apparatus 30, and is any of an antenna, a cable, and the like, for example. The communication unit 42 may perform communication with the external apparatus in accordance with an arbitrary communication method.

The storage unit 43 is a memory that stores a variety of information such as contents of operations by the control unit 450 and programs, and includes at least one of a main storage device such as a RAM (random access memory) and a ROM (read only memory), and an external storage device such as an HDD (hard disk drive) and an SSD (solid state drive), for example. The programs for the control unit 450 stored by the storage unit 43 may be stored in a storage medium readable by the information processing apparatus 40.

The output unit 44 outputs a variety of information including the dielectric characteristics calculated by the information processing apparatus 40. The output unit 44 is a display unit, for example.

The control unit 450 is an operating device that includes the operating circuit such as the CPU. The control unit 450 includes a measurement control unit 451 and a dielectric characteristic calculation unit 452. The control unit 450 executes processing by reading a program (the software) out of the storage unit 43 and executing the program. Here, the control unit 450 may execute the processing with a single CPU, or may include multiple CPUs and execute the processing with the multiple CPUs. Meanwhile, processing by the dielectric characteristic calculation unit 452 may be implemented by a hardware circuit.

The measurement control unit 451 obtains measurement parameters of the measurement apparatus 30 (see FIG. 1) from the input unit 41, and controls a measurement operation by the measurement apparatus 30 in accordance with the measurement parameters. For example, the measurement parameters include the start frequency, the stop frequency, the intensity of the input wave, and the like. Here, the measurement control unit 451 may obtain the measurement parameters of the measurement apparatus 30 by reading information stored in the storage unit 43.

The dielectric characteristic calculation unit 452 obtains information concerning the measurement and calculates the dielectric characteristics of the dielectric layers 131 and 132. The information concerning the measurement is information including numerical values and the like of the S parameters, the diameters a of the first communication hole 113 and the second communication hole 123, the thicknesses t of the dielectric layers 131 and 132, the radius R of the circular conductor foil 133, and conductivity σ of the circular conductor foil 133. The dielectric characteristic calculation unit 452 obtains the information concerning the measurement from the input unit 41 and the communication unit 42. Based on the information concerning the measurement, the dielectric characteristic calculation unit 452 calculates relative permittivity εᵣ′ and dielectric tangent tan δ as the dielectric characteristics of the dielectric layers 131 and 132. The dielectric characteristic calculation unit 452 controls the output unit 44 and causes the output unit 44 to display the information indicating the dielectric characteristics of the dielectric layers 131 and 132 inclusive of the relative permittivity εᵣ′ and the dielectric tangent tan δ thus calculated.

Here, the relative permittivity εᵣ′ is a real part of complex relative permittivity εᵣ defined in the following formula (10). In the formula (10), j is imaginary unit. Meanwhile, the dielectric tangent tan δ is a parameter defined in the following formula (11), which is a ratio of an imaginary part εᵣ″ of the complex relative permittivity εᵣ to the relative permittivity εᵣ′.

$$[ Math . 10 ]$$

$${ε}_{r} = {ε}_{γ}^{′} - j {ε}_{r}^{″} \qquad ( 10 )$$

$$[ Math . 11 ]$$

$$tan δ = \frac{{ε}_{r}^{″}}{{ε}_{r}^{′}} \qquad ( 11 )$$

The dielectric characteristic calculation unit 452 calculates the relative permittivity εᵣ′ by solving an equation defined in the following formula (12). In the formula (12), H is a matrix containing elements of εᵣ′, f₀ₘ₀, t, R, a, and M as variables. f₀ₘ₀ denotes the resonant frequency, which is a value of the frequency at an apex of a peak in the graph of the bandpass coefficient |S₂₁| relative to the measurement frequency. M denotes a parameter concerning the shape of the resonator, which is a constant in the case of the resonator 100 according to the first embodiment.

$$[ Math . 12 ]$$

$$det H ( {ε}_{r}^{′} , {f}_{0 mo} , t , R , a , M ) = 0 \qquad ( 12 )$$

The dielectric characteristic calculation unit 452 calculates the dielectric tangent tan δ in accordance with the following formula (13) and formula (14). Here, in the formula (13), Qᵤ denotes a Q factor at no load, Q_{c} denotes a Q factor due to a conductor loss, W₁ denotes electrical energy accumulated between the dielectric layers 131 as well as 132 and the circular conductor foil 133, and W₂ denotes electrical energy accumulated between the first communication hole 113 and the second communication hole 123. The Q factor Qᵤ at no load is calculated based on the resonant frequency f₀ₘ₀ and the 3-dB band width at the relevant resonant frequency in the graph of the bandpass coefficient |S₂₁| relative to the measurement frequency. The Q factor Q_{c} due to the conductor loss is obtained by the following formula (14). In the formula (14), μ₀ denotes the magnetic constant of the free space. The values of the electrical energy W₁ and W₂ are calculated by an analysis.

$$[ Math . 13 ]$$

$$tan δ = ( \frac{1}{{Q}_{u}} - \frac{1}{{Q}_{c}} ) ( 1 + \frac{{W}_{1}}{{W}_{2}} ) \qquad ( 13 )$$

$$[ Math . 14 ]$$

$${Q}_{c} = t \sqrt{π {f}_{0 m 0} {μ}_{0} σ} \qquad ( 14 )$$

The dielectric characteristic measurement system 1 according to the first embodiment has been described above. However, the above-described aspect is merely one example and the present disclosure is not limited thereto. For example, the transmission unit, the reception unit, and the information processing unit may be implemented by a single apparatus or may be implemented by different apparatuses from one another. Meanwhile, the information to be transmitted from the measurement apparatus 30 to the information processing apparatus 40 is not limited to the S parameters, and numerical values of the resonant frequency f₀ₘ₀, the 3-dB band width at the peak of the resonant frequency f₀ₘ₀, and the like may also be transmitted. In the meantime, the measurement apparatus 30 is not bound to transmit the information concerning the measurement to the information processing apparatus 40. For example, the measurement apparatus 30 may cause an information storage medium such as a USB memory to store the information concerning the measurement, and the information processing apparatus 40 may obtain the information concerning the measurement by reading the information storage medium.

As described above, the dielectric characteristic measurement system 1 according to the first embodiment includes the resonator 100, the transmission unit that transmits the input wave to the resonator 100, the reception unit that receives the output wave from the resonator 100, and the information processing unit that calculates the dielectric characteristics of the dielectric layers 131 and 132. In this way, it is possible to measure the dielectric characteristics at the high frequency band with the simple structure.

The transmission unit (the measurement apparatus 30) may sweep the input wave in the measurement frequency band equal to or above the start frequency fₗ and equal to or below the stop frequency fₕ, and transmits the input wave. The cutoff frequency f_{c1} in the basic mode of the first waveguide 110 is equal to or below the start frequency fₗ. The cutoff frequency f_{c2} in the secondary mode of the first waveguide 110 is larger than the stop frequency fₕ. The cutoff frequency in the basic mode of the second waveguide 120 is equal to or below the start frequency fₗ. The cutoff frequency in the secondary mode of the second waveguide is larger than the stop frequency fₕ. Accordingly, the first waveguide 110 and the second waveguide 120 propagate the input wave or the output wave throughout the measurement frequency band while cutting off the high-order mode, and can therefore appropriately measure the dielectric characteristics.

The length d₁ of the inner wall of the first communication hole 113 in the first direction may be equal to or below 0.4 times of a free space wavelength of an electromagnetic wave at the stop frequency fₕ, and the length d₂ of the inner wall of the second communication hole 123 in the first direction is equal to or below 0.4 times of the free space wavelength of the electromagnetic wave at the stop frequency fₕ. Accordingly, the first communication hole 113 can cause the evanescent wave from the first propagation path 111 to transition to the multilayer body 130 at a sufficient intensity, and the second communication hole 123 can cause the evanescent wave from the multilayer body 130 to transition to the second propagation path 121 at a sufficient intensity.

The first communication hole 113 and the second communication hole 123 may be circular in plan view in the first direction. The diameter a₁ of the first communication hole 113 in plan view in the first direction is equal to or above 0.2 times of the free space wavelength of the electromagnetic wave at the start frequency fₗ and is equal to or below 0.4 times of the free space wavelength at the stop frequency fₕ. The diameter a₂ of the second communication hole 123 in plan view in the first direction is equal to or above 0.2 times of the free space wavelength of the electromagnetic wave at the start frequency fₗ and is equal to or below 0.4 times of the free space wavelength at the stop frequency fₕ. Accordingly, the first communication hole 113 can cause the evanescent wave at a sufficient intensity for excitation to transition to the multilayer body 130, and the second communication hole 123 can cause only the evanescent wave at a sufficient intensity to transition to the second propagation path 121.

A dielectric characteristic measuring method according to the first embodiment will be described below. The dielectric characteristic measuring method according to the first embodiment includes a step of transmitting an input wave to the resonator 100, a step of receiving an output wave from the resonator 100, and a step of calculating dielectric characteristics of the dielectric layers 131 and 132. While the respective steps will be described below, it is to be noted that the following description is merely one example and the present disclosure is not limited to this method.

As a first step, the input wave is transmitted to the resonator 100. Transmission of the input wave is carried out, for example, by transmitting an electromagnetic wave at a low frequency from the measurement apparatus 30 being the transmission unit to the converter 20A, then converting this wave into an electromagnetic wave at a high frequency with the converter 20A, and inputting this wave to the first connecting portion 112 of the resonator 100 via the waveguide 21A. In the first embodiment, transmission of the input wave is carried out by sweeping the frequency.

The input wave inputted to the first connecting portion 112 of the resonator 100 is propagated on the first propagation path 111 of the first waveguide 110, and is caused to transition to the multilayer body 130 as the evanescent wave by using the first communication hole 113. In this instance, resonance due to electric field coupling occurs on a line including the first waveguide 110, the second waveguide 120, and the multilayer body 130, whereby the TM₀ₘ₀ mode is excited in accordance with the dielectric characteristics of the dielectric layers 131 and 132. The excited wave (the resonant wave) is caused to transition to the second waveguide 120 as the evanescent wave by using the second communication hole 123. The transitioning electromagnetic wave is propagated on the second propagation path 121 as the output wave, and is output from the second connecting portion 122.

As a second step, the output wave is received from the resonator 100. Reception of the output wave is carried out, for example, by converting an electromagnetic wave at a high frequency from the second connecting portion 122 of the resonator 100 is converted into a low frequency with the converter 20B via the waveguide 21B, and receiving this wave with the measurement apparatus 30 being the reception unit. The step of receiving the output wave from the resonator 100 is carried out simultaneously with the step of transmitting the input wave. The measurement apparatus 30 measures the S parameters of the circuit that involves the resonator 100 as the measurement target, and transmits the values of the S parameters corresponding to the frequency of the input wave to the information processing apparatus 40.

As a third step, the dielectric characteristics of the dielectric layers 131 and 132 are calculated. Calculation of the dielectric characteristics of the dielectric layers 131 and 132 is carried out by the information processing apparatus 40 based on measurement information. To be more precise, the parameters such as resonant frequencies f₀ₘ₀ and the Q factors Qᵤ at no load of the dielectric layers 131 and 132 are calculated from the S parameters concerning the resonator 100, thereby calculating the relative permittivity εᵣ′ and the dielectric tangent tan δ of each of the dielectric layers 131 and 132.

As described above, the dielectric characteristic measuring method according to the first embodiment includes the step of transmitting an input wave to the resonator 100, the step of receiving an output wave from the resonator 100, and the step of calculating dielectric characteristics of the dielectric layers 131 and 132. In this way, the dielectric characteristics at the high frequency band may be measured with the simple structure.

### Second Embodiment

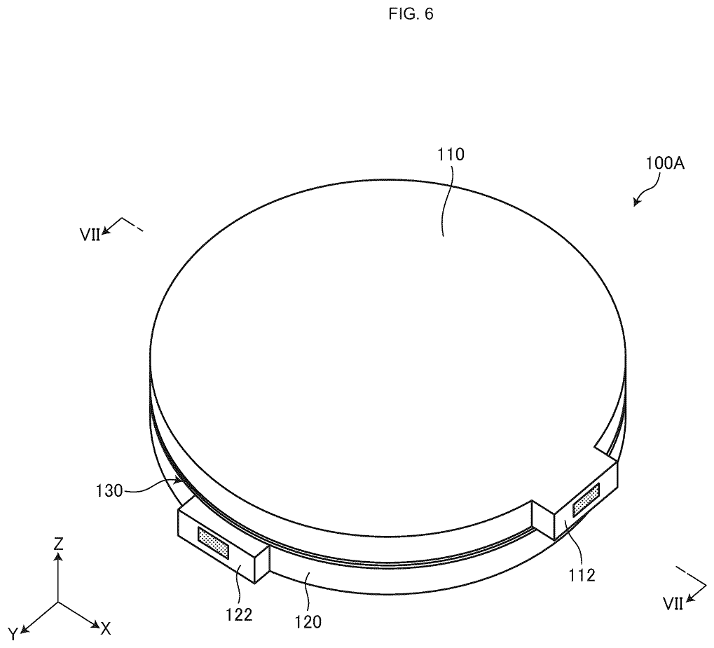

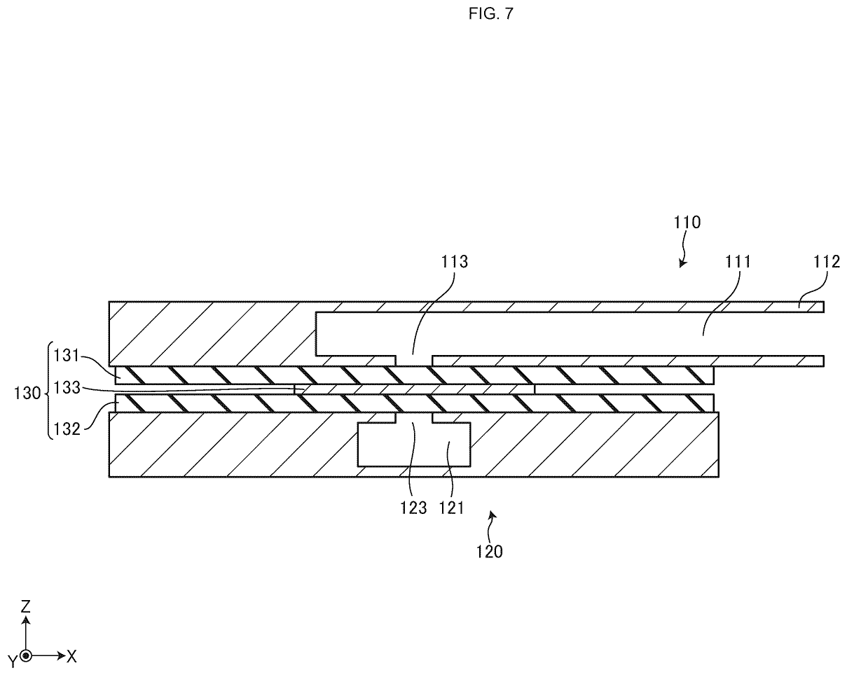

FIG. 6 is a perspective view showing a resonator according to a second embodiment. FIG. 7 is a cross-sectional view taken along line VII-VII in FIG. 6. As shown in FIG. 6 and FIG. 7, a resonator 100A according to the second embodiment is different from the first embodiment in that a direction of propagation of the first propagation path 111 in the first communication hole 113 is a different direction from a direction of propagation of the second propagation path 121 in the second communication hole 123. The resonator 100A according to the second embodiment will be described below. Note that the same structures as those of the first embodiment will be denoted by the same reference signs and explanations thereof will be omitted.

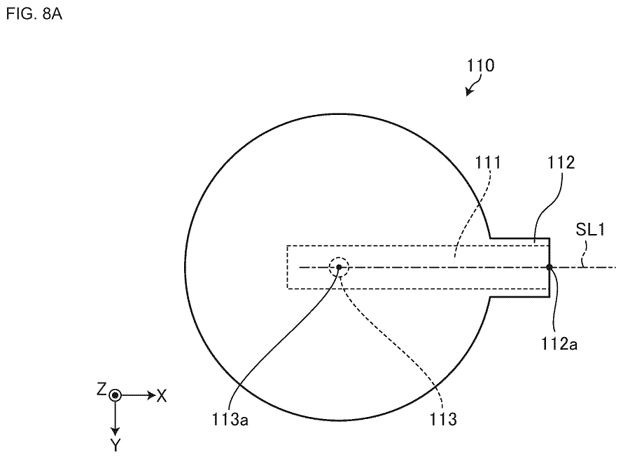

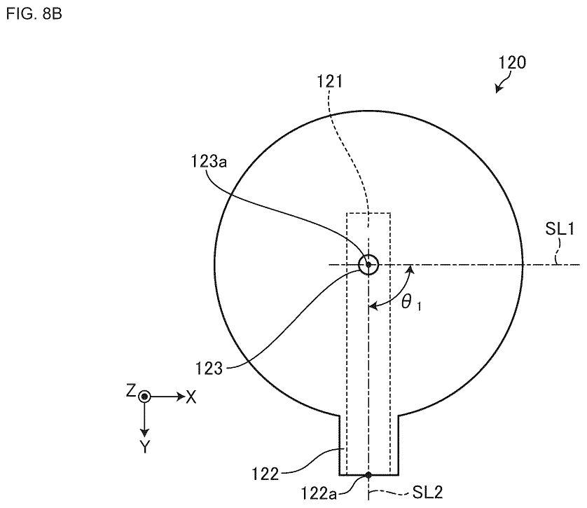

FIG. 8A is a plan view of a first waveguide according to the second embodiment. FIG. 8B is a plan view of a second waveguide according to the second embodiment. In the second embodiment, the straight line SL1 that passes through the circular center 113a of the first communication hole 113 and the center 112a of the cavity of the first connecting portion 112 crosses the straight line SL2 that passes through the circular center 123a of the second communication hole 123 and the center 122a of the cavity of the second connecting portion 122. In the example of FIG. 8B, the straight line SL2 that connects the circular center 123a of the second communication hole 123 to the center 122a of the cavity of the second connecting portion 122 is parallel to the y direction. Thus, an angle θ₁ formed between the straight line SL1 and the straight line SL2 is 90°. In other words, the resonator 100A according to FIG. 6 is equivalent to a structure formed by rotating the second waveguide 120 of the resonator 100 according to the first embodiment by 90° pivotally about a straight line passing through the second communication hole 123 and being parallel to the z direction. In this way, an unnecessary mode originating from the direction of propagation of the first propagation path 111 may be kept from being propagated in the second propagation path 121 as well. Thus, the occurrence of an unnecessary wave can be suppressed.

As described above, in the resonator 100A according to the second embodiment, the direction of propagation of the first propagation path 111 is a different direction from the direction of propagation of the second propagation path 121 in plan view in the first direction. In this way, it is possible to keep an unnecessary mode originating from the direction of propagation of the first propagation path 111 from being propagated in the second propagation path 121 as well. Thus, the occurrence of an unnecessary wave can be suppressed.

### Third Embodiment

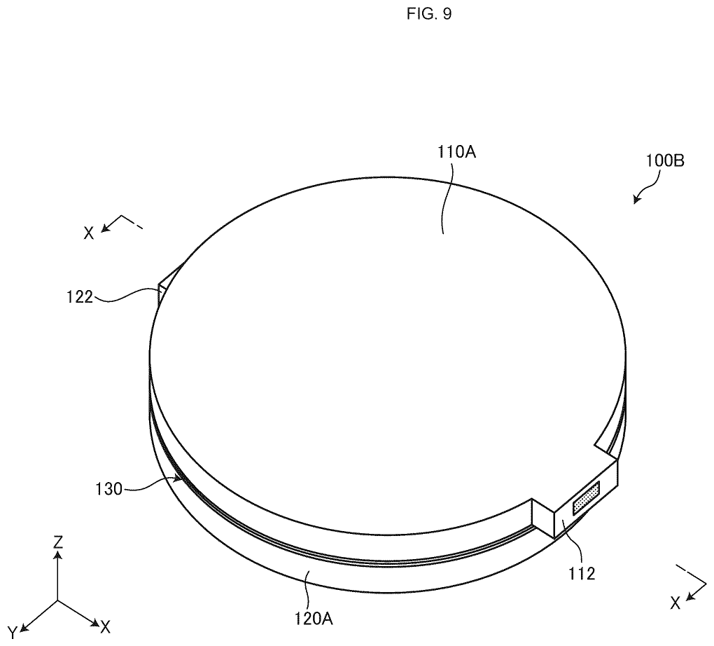

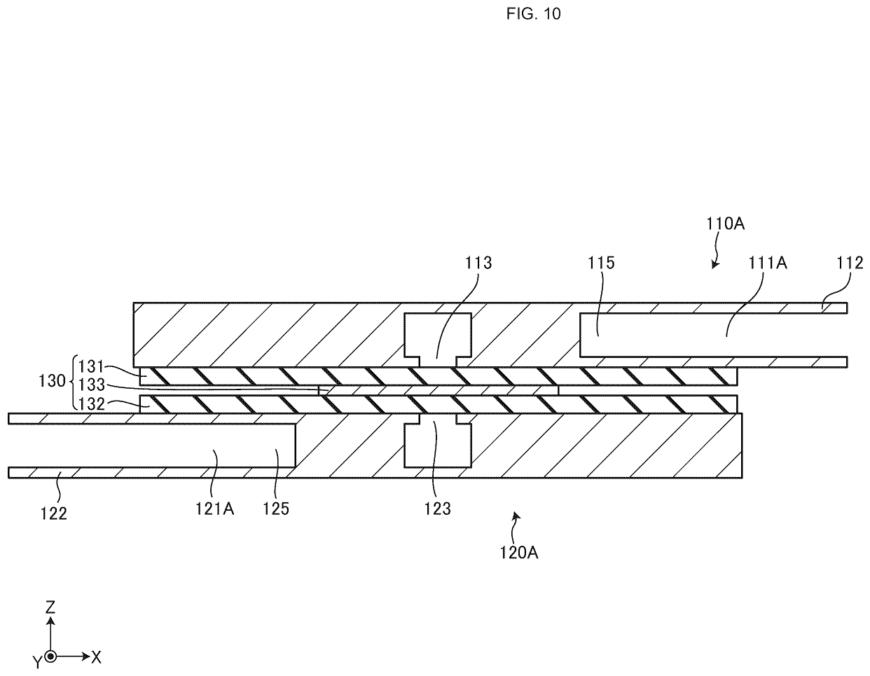

FIG. 9 is a perspective view of a resonator according to a third embodiment. FIG. 10 is a cross-sectional view taken along line X-X in FIG. 9. A resonator 100B according to the third embodiment is different from the first embodiment in that each propagation path includes multiple branched propagation paths between the connecting portion and the communication hole. The resonator 100B according to the third embodiment will be described below. Note that the same structures as those of the first embodiment will be denoted by the same reference signs and explanations thereof will be omitted.

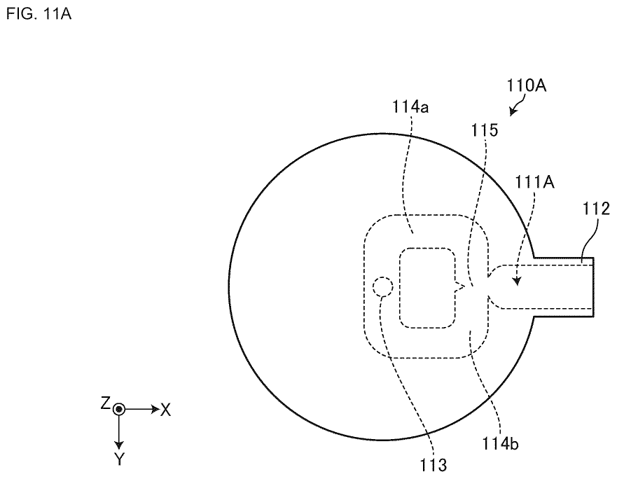

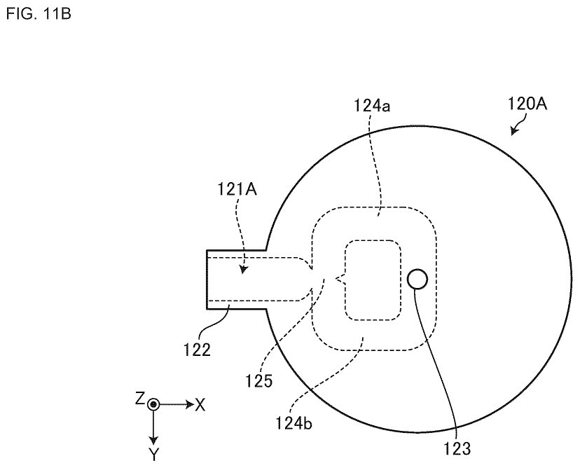

FIG. 11A is a plan view of a first waveguide according to the third embodiment. As shown in FIG. 11A, a first propagation path 111A according to the third embodiment includes a first branched propagation path 114a and a second branched propagation path 114b between the first connecting portion 112 and the first communication hole 113. In the example of FIG. 11A, the first propagation path 111A branches into the first branched propagation path 114a and the second branched propagation path 114b at a first branch 115, which join together at the first communication hole 113. Thus, in the first propagation path 111A, the first branched propagation path 114a and the second branched propagation path 114b communicate with each other at the first communication hole 113. Meanwhile, the first branch 115 communicates with the first branched propagation path 114a, the second branched propagation path 114b, and the cavity of the first connecting portion 112.

The first branched propagation path 114a and the second branched propagation path 114b are spaces in the first waveguide 110 where the input wave is branched off and propagated in the z direction. A shape of an inner wall of each of the first branched propagation path 114a and the second branched propagation path 114b has such a shape that changes a direction of the propagation path on the way. Specifically, a first waveguide 110A according to the third embodiment is a so-called curved waveguide. A shape of a curved portion of the inner wall of each of the first branched propagation path 114a and the second branched propagation path 114b may be a broken line shape or a curved line shape in plan view in the z direction. In other words, the first waveguide 110A may be either a so-called corner waveguide or a bend waveguide. A length along the direction of propagation of the first propagation path 111A from the first connecting portion 112 to the first communication hole 113 is equal between the propagation path routed through the first branched propagation path 114a and the propagation path routed through the second branched propagation path 114b. In other words, a length along the direction of propagation from the first branch 115 to the first communication hole 113 of the first branched propagation path 114a is equal to that of the second branched propagation path 114b. This configuration suppresses the occurrence of an unnecessary mode originating from the direction of propagation of the first propagation path 111A so that the occurrence of an unnecessary wave can be suppressed. Meanwhile, the input wave may be kept from being reflected from the inner wall of the first propagation path 111A and returning to the first connecting portion 112 side, so that attenuation of the output wave due to the reflected wave can be suppressed.

In the example of FIG. 11A, in plan view in the z direction, the shape of the inner wall of each of the first branched propagation path 114a and the second branched propagation path 114b is formed into such a shape that proceeds in one orientation in the y direction from the first branch 115, then proceeds toward the first communication hole 113 in the x direction, and then proceeds in the other orientation in the y direction until reaching the first communication hole 113. In other words, the first branched propagation path 114a and the second branched propagation path 114b are formed into such shapes that proceed in different orientations in the y direction from each other at the first branch 115, then proceed toward the first communication hole 113 in the x direction, then proceed in such a way as to be opposed to each other in the y direction, and join together at the first communication hole 113. Accordingly, in this case, the shapes of the inner walls of the first branched propagation path 114a and the second branched propagation path 114b are line-symmetric with respect to the x direction as the axis of symmetry in plan view in the z direction. Thus, the lengths of the first branched propagation path 114a and the second branched propagation path 114b from the first branch 115 to the first communication hole 113 along the direction of propagation are equal.

The first branch 115 is provided between the first connecting portion 112 and the first communication hole 113 in plan view in the z direction. The first branch 115 is a space corresponding to inside of a so-called bifurcation element that allocates the input wave from the first connecting portion 112 to the first branched propagation path 114a and the second branched propagation path 114b. In the example of FIG. 11A, a shape of an inner wall of the first branch 115 is a T-shape in plan view in the z direction, which is a shape that extends in two directions, namely, an orientation on the first connecting portion 112 side of the x direction, and the y direction. Here, the shape of the inner wall of the first branch 115 is not limited to the T-shape, i.e., any shape that shape extends in three directions in plan view in the z direction, e.g., a Y-shape, may be used. Meanwhile, in the example of FIG. 11A, the first branch 115 includes an inner wall at a portion extending in the x direction and a projection bulging from an inner wall at a portion extending in the y direction. However, this is merely an example.

FIG. 11B is a plan view of a second waveguide according to the third embodiment. As shown in FIG. 11B, a second propagation path 121 according to the third embodiment includes a third branched propagation path 124a and a fourth branched propagation path 124b between the second connecting portion 122 and the second communication hole 123. In the example of FIG. 11B, a second propagation path 121A branches into the third branched propagation path 124a and the fourth branched propagation path 124b at the second communication hole 123, which join together at a second branch 125. Thus, in the second propagation path 121, the third branched propagation path 124a and the fourth branched propagation path 124b communicate with each other at the second communication hole 123. Meanwhile, the second branch 125 communicates with the third branched propagation path 124a, the fourth branched propagation path 124b, and the cavity of the second connecting portion 122.

The third branched propagation path 124a and the fourth branched propagation path 124b are spaces in the second waveguide 120 where the output wave is branched off and propagated in the z direction. A shape of an inner wall of each of the third branched propagation path 124a and the fourth branched propagation path 124b has such a shape that changes a direction of the propagation path on the way. Specifically, a second waveguide 120A according to the third embodiment is a so-called curved waveguide. A shape of a curved portion of the inner wall of each of the third branched propagation path 124a and the fourth branched propagation path 124b may be a broken line shape or a curved line shape in plan view in the z direction. In other words, the second waveguide 120A may be either a so-called corner waveguide or a bend waveguide. A length along the direction of propagation of the second propagation path 121A from the second communication hole 123 to the second connecting portion 122 is equal between the propagation path routed through the third branched propagation path 124a and the propagation path routed through the fourth branched propagation path 124b. In other words, a length along the direction of propagation from the second communication hole 123 to the second branch 125 of the third branched propagation path 124a is equal to that of the fourth branched propagation path 124b. This configuration suppresses propagation of the unnecessary mode originating from the direction of propagation of the first propagation path 111A on the second propagation path 121A as well, so that the occurrence of the unnecessary wave can be suppressed.

In the example of FIG. 11B, in plan view in the z direction, the shape of the inner wall of each of the third branched propagation path 124a and the fourth branched propagation path 124b is formed into such a shape that proceeds in one orientation in the y direction from the second communication hole 123, then proceeds toward the second branch 125 in the x direction, and then proceeds in the other orientation in the y direction until reaching the second branch 125. In other words, the third branched propagation path 124a and the fourth branched propagation path 124b are formed into such shapes that proceed in different orientations in the y direction from each other at the second communication hole 123, then proceed toward the second branch 125 in the x direction, then proceed in such a way as to be opposed to each other in the y direction, and join together at the second branch 125. Accordingly, in this case, the shapes of the inner walls of the third branched propagation path 124a and the fourth branched propagation path 124b are line-symmetric with respect to the x direction as the axis of symmetry in plan view in the z direction. Thus, the lengths of the third branched propagation path 124a and the fourth branched propagation path 124b from the second communication hole 123 to the second branch 125 along the direction of propagation are equal.

The second branch 125 is provided between the second connecting portion 122 and the first communication hole 113 in plan view in the z direction. The second branch 125 is a space corresponding to inside of a so-called bifurcation element that joins the output waves from the third branched propagation path 124a and the fourth branched propagation path 124b together to the second connecting portion 122. In the example of FIG. 11B, a shape of an inner wall of the second branch 125 is a T-shape in plan view in the z direction, which is a shape that extends in two directions, namely, an orientation on the second connecting portion 122 side of the x direction, and the y direction. Here, the shape of the inner wall of the second branch 125 is not limited to the T-shape as long as it is a shape extending in three directions in plan view in the z direction, and may be a Y-shape, for example. Meanwhile, in the example of FIG. 11B, the second branch 125 includes an inner wall at a portion extending in the x direction and a projection bulging from an inner wall at a portion extending in the y direction. However, this is merely an example.

As described above, in the resonator 100B according to the third embodiment, the first propagation path 111A includes the first branched propagation path 114a and the second branched propagation path 114b between the first connecting portion 112 and the first communication hole 113, and the length along the direction of propagation of the first propagation path 111A from the first connecting portion 112 to the first communication hole 113 is equal between the propagation path routed through the first branched propagation path 114a and the propagation path routed through the second branched propagation path 114b. Accordingly, the occurrence of an unnecessary mode originating from the direction of propagation of the first propagation path 111 may be suppressed so that the occurrence of an unnecessary wave can be suppressed. Meanwhile, the input wave may be kept from being reflected from the inner wall of the first propagation path 111A and returning to the first connecting portion 112 side, so that attenuation of the output wave due to the reflected wave can be suppressed.

In the meantime, in the resonator 100B according to the third embodiment, the second propagation path 121A includes the third branched propagation path 124a and the fourth branched propagation path 124b between the second communication hole 123 and the second connecting portion 122, and the length along the direction of propagation of the second propagation path 121A from the second communication hole 123 to the second connecting portion 122 is equal between the propagation path routed through the third branched propagation path 124a and the propagation path routed through the fourth branched propagation path 124b. Accordingly, an unnecessary mode originating from the direction of propagation of the first propagation path 111 may be kept from being propagated in the second propagation path 121 as well. Thus, the occurrence of an unnecessary wave can be suppressed.

### Fourth Embodiment

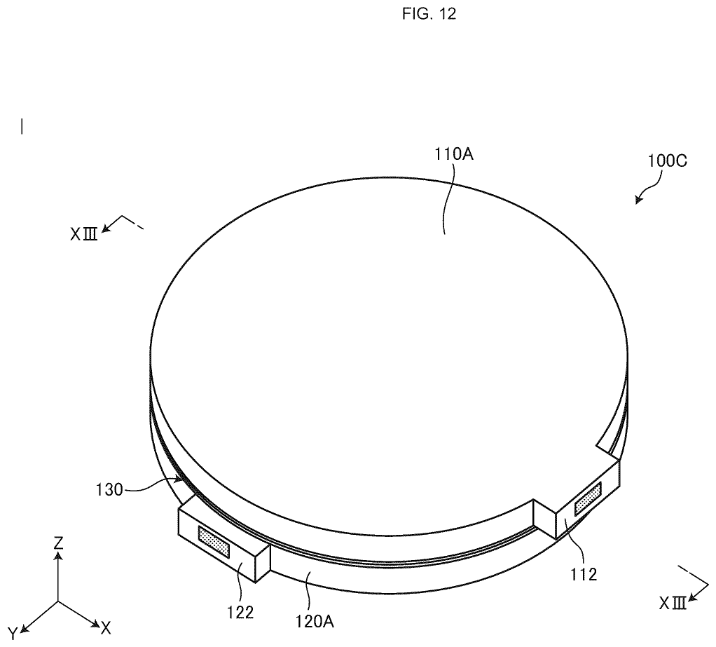

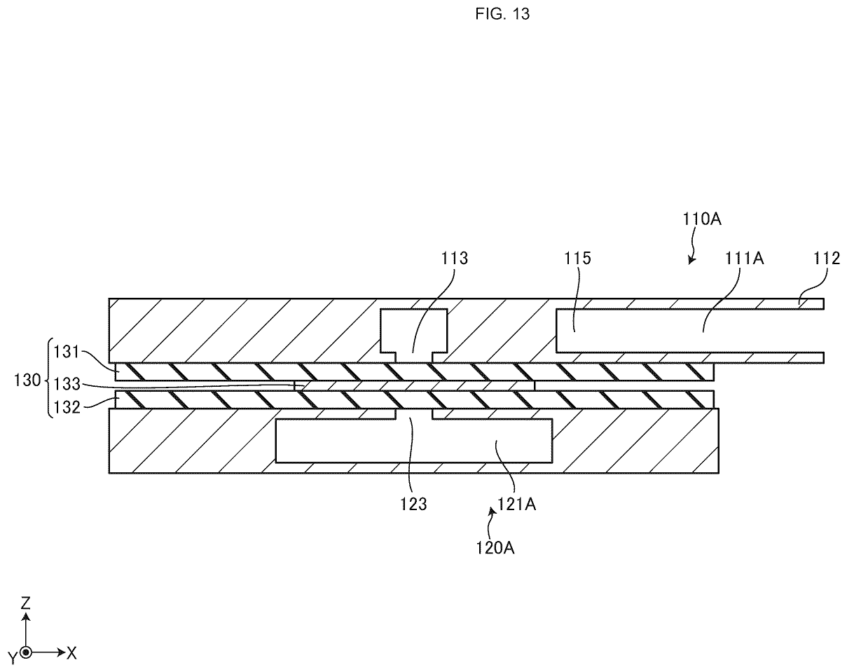

FIG. 12 is a perspective view of a resonator according to a fourth embodiment. FIG. 13 is a cross-sectional view taken along line XIII-XIII in FIG. 12. A resonator 100C according to the fourth embodiment is different from the third embodiment in that a direction of propagation of the first propagation path 111A in the first communication hole 113 is a different direction from a direction of propagation of the second propagation path 121A in the second communication hole 123. Note that the same structures as those of the third embodiment will be denoted by the same reference signs and explanations thereof will be omitted.

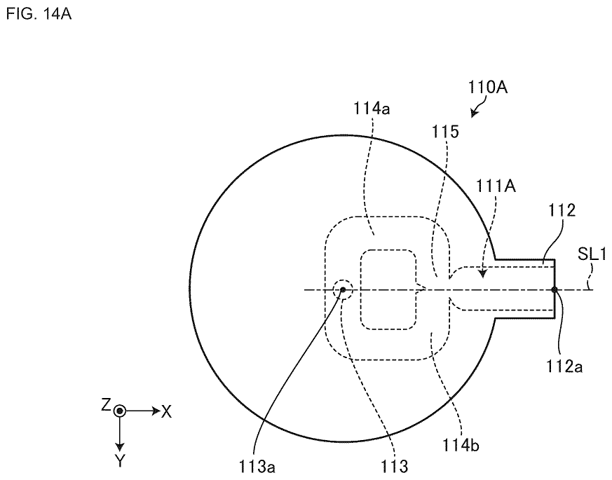

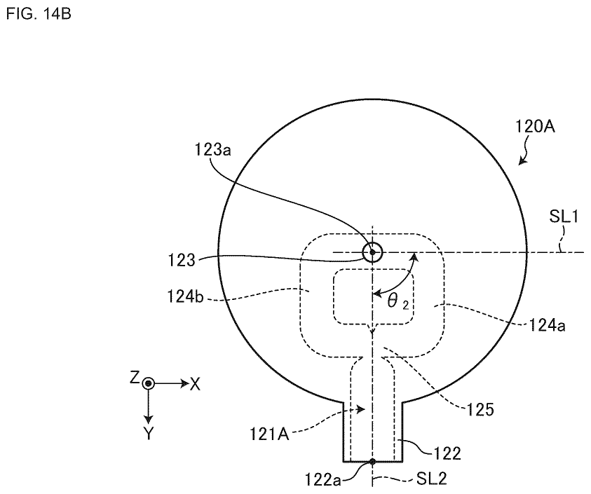

FIG. 14A is a plan view of showing a first waveguide according to the fourth embodiment. FIG. 14B is a plan view showing a second waveguide according to the fourth embodiment. In the fourth embodiment, the straight line SL1 that passes through the circular center 113a of the first communication hole 113 and the center 112a of the cavity of the first connecting portion 112 crosses the straight line SL2 that passes through the circular center 123a of the second communication hole 123 and the center 122a of the cavity of the second connecting portion 122. In the example of FIG. 14B, the straight line SL2 that connects the circular center 123a of the second communication hole 123 to the center 122a of the cavity of the second connecting portion 122 is parallel to the y direction. Thus, an angle θ₂ formed between the straight line SL1 and the straight line SL2 is 90°. In other words, the resonator 100C according to FIG. 12 is equivalent to a structure formed by rotating the second waveguide 120 of the resonator 100B according to the third embodiment by 90° pivotally about a straight line passing through the second communication hole 123 and being parallel to the z direction. In this way, an unnecessary mode originating from the direction of propagation of the first propagation path 111A may be kept from being propagated in the second propagation path 121A as well. Thus, the occurrence of an unnecessary wave can be suppressed. Meanwhile, the input wave may be prevented from being reflected from the inner wall of the first propagation path 111A and returning to the first connecting portion 112 side, so that attenuation of the output wave due to the reflected wave can be suppressed.

### EXAMPLES

Examples according to first to third tests will be described below. Note that the resonator and the dielectric characteristic measurement system according to the present disclosure are not limited to the examples described below. The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples

### (First Test)

In a first test, the reflection coefficient |S₁₁| and the bandpass coefficient |S₂₁| were obtained by means of electromagnetic field simulation in the measurement frequency band equal to or above 110 GHz and equal to or below 170 GHz in accordance with measuring methods from Example 1 to Example 4 while changing the resonators.

In Example 1, the resonator 100 according to the first embodiment was used as the resonator. Here, the cross-sectional shape of each of the first waveguide 110 and the second waveguide 120 according to Example 1 is a rectangle of which the lengths l₁ and l₂₁ of the long sides are 1.651 mm and the lengths l₁₂ and l₂₂ of the short sides are 0.825 mm.

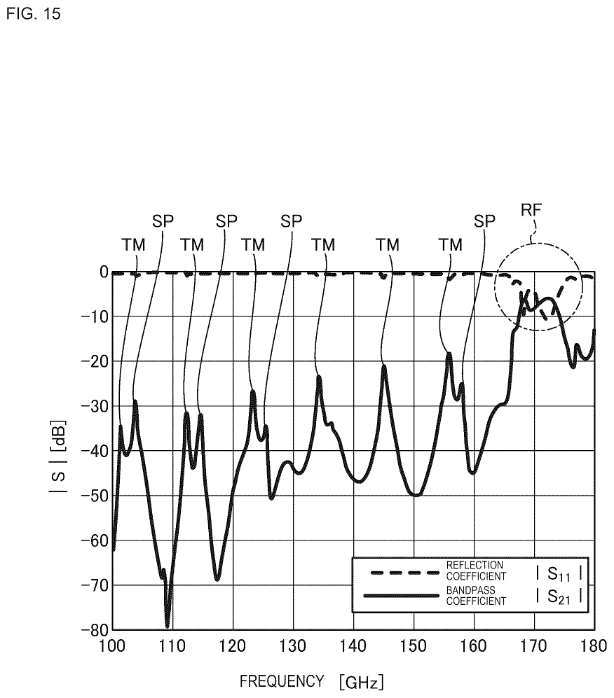

FIG. 15 is a diagram depicting a graph showing a result of measurement of the reflection coefficient and the bandpass coefficient according to Example 1. As shown in FIG. 15, in the measurement according to Example 1, peaks TM that represent the resonant waves appear in the graph of the bandpass coefficient |S₂₁|. Meanwhile, in Example 1, peaks SP that represent unnecessary waves appear in the graph of the bandpass coefficient |S₂₁|. On the other hand, in the measurement according to Example 1, peaks RF that represent reflected waves appear in a high frequency band in the graph of the reflection coefficient |S₁₁|.

Therefore, it turns out that the dielectric characteristics can be measured in the measurement frequency band equal to or above 110 GHz and equal to or below 170 GHz in accordance with the measuring method of Example 1. In the meantime, it turns out that the unnecessary waves and the reflected waves of the input wave occur in the measurement according to Example 1.

In Example 2, the resonator 100A according to the second embodiment was used as the resonator. The cross-sectional shapes of the first waveguide 110 and the second waveguide 120 according to Example 2 are the same as those of Example 1.

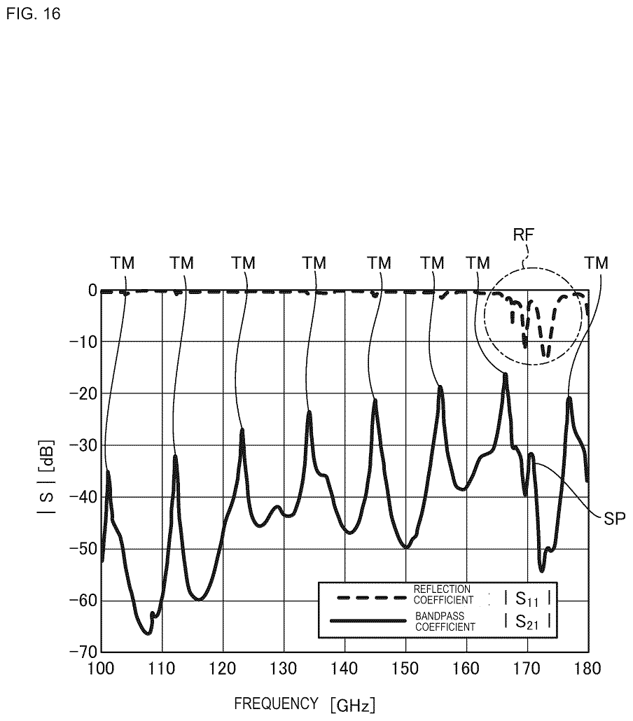

FIG. 16 is a diagram depicting a graph showing a result of simulation of the reflection coefficient and the bandpass coefficient according to Example 2. As shown in FIG. 16, in the measurement according to Example 2, peaks TM that represent the resonant waves appear in the graph of the bandpass coefficient |S₂₁|. In Example 2, peaks SP that represent the unnecessary waves are reduced as compared to Example 1 in the graph of the bandpass coefficient |S₂₁|. On the other hand, in Example 2, the peaks RF that represent the reflected waves appear in a high frequency band in the graph of the reflection coefficient |S₁₁|.

Therefore, the dielectric characteristics can be measured more appropriately in accordance with the measuring method of Example 2 as compared to Example 1 since the occurrence of the unnecessary waves is suppressed. In the meantime, it turns out that the reflected waves of the input wave occur in the measurement according to Example 2. A reason why the occurrence of the unnecessary waves is suppressed in the measurement according to Example 2 is considered to be because the direction of propagation of the first propagation path 111 in the first communication hole 113 is perpendicular to the direction of propagation of the second propagation path 121 in the second communication hole 123 in plan view in the first direction, and the unnecessary mode originating from the direction of propagation of the first propagation path 111 is therefore less likely to be propagated in the second propagation path 121.

In Example 3, the resonator 100B according to the third embodiment was used as the resonator. The cross-sectional shapes of the first waveguide 110A and the second waveguide 120A according to Example 3 are the same as those of Example 1.

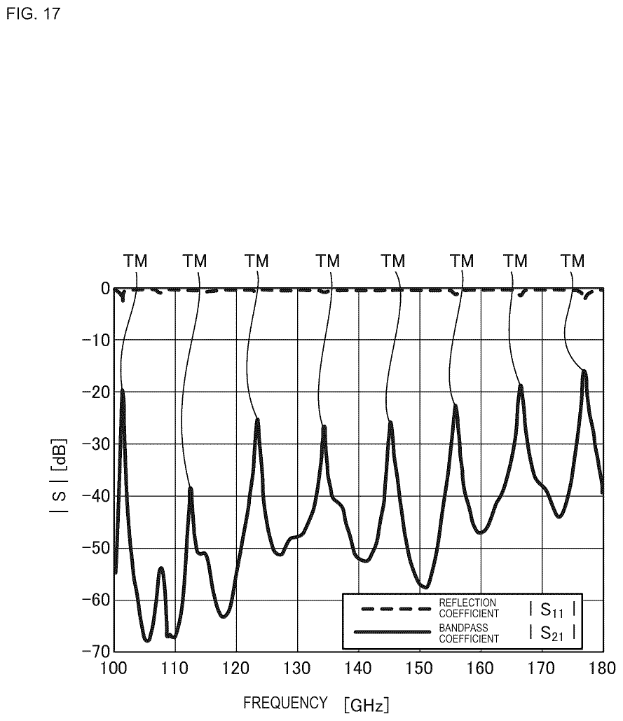

FIG. 17 is a diagram depicting a graph showing a result of simulation of the reflection coefficient and the bandpass coefficient according to Example 3. As shown in FIG. 17, in Example 3 as well, peaks TM that represent the resonant waves appear in the graph of the bandpass coefficient |S₂₁| In Example 3, peaks that represent the unnecessary waves are reduced as compared to Example 1 and Example 2 in the graph of the bandpass coefficient |S₂₁|. Meanwhile, in Example 3, peaks that represent the reflected waves are reduced in a high frequency band in the graph of the reflection coefficient |S₁₁|.

Therefore, it turns out that the dielectric characteristics can be measured more appropriately in accordance with the measuring method of Example 3 as compared to Example 1 and Example 2 since the occurrence of the unnecessary waves and the input wave is suppressed. A reason why the occurrence of the unnecessary waves and the reflected waves of the input wave is suppressed in the measurement according to Example 3 is considered to be because each propagation path includes two branched propagation paths between the connecting portion and the communication hole.

In Example 4, the resonator 100C according to the fourth embodiment was used as the resonator. The cross-sectional shapes of the first waveguide 110A and the second waveguide 120A according to Example 3 are the same as those of Example 1.

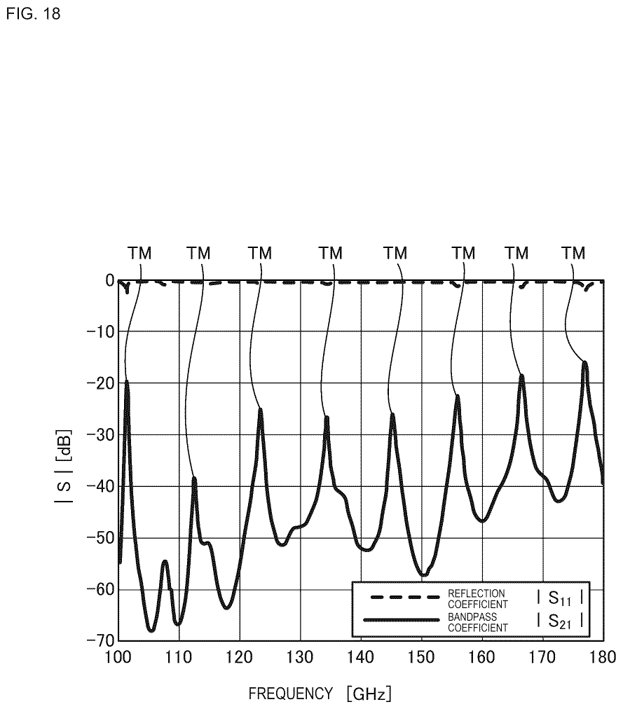

FIG. 18 is a diagram depicting a graph showing a result of simulation of the reflection coefficient and the bandpass coefficient according to Example 4. As shown in FIG. 18, in Example 4 as well, peaks TM that represent the resonant waves appear in the graph of the bandpass coefficient |S₂₁| In Example 4, peaks that represent the unnecessary waves are reduced as compared to Example 1 and Example 2 in the graph of the bandpass coefficient |S₂₁|. Meanwhile, in Example 4, peaks that represent the reflected waves are reduced in a high frequency band in the graph of the reflection coefficient |S₁₁|.

Therefore, it turns out that the dielectric characteristics can be measured more appropriately in accordance with the measuring method of Example 3 as compared to Example 1 and Example 2 since the occurrence of the unnecessary waves and the input wave is suppressed. A reason why the occurrence of the unnecessary waves and the reflected waves of the input wave is suppressed in the measurement according to Example 3 is considered to be because each propagation path includes two branched propagation paths between the connecting portion and the communication hole.

### (Second Test)

In a second test, simulation models of resonators according to Example 5, Comparative Example 1, and Comparative Example 2 were created while changing the diameters a of the first communication hole 113 and the second communication hole 123. In the second test, simulation of measurement values of the relative permittivity εᵣ′ and the resonant frequency f₀ₘ₀ in the measurement frequency band equal to or above 110 GHz and equal to or below 170 GHz was carried out by using the simulation models of the resonators according to Example 5, Comparative Example 1, and Comparative Example 2. In the second test, the simulation was conducted on the assumption that the relative permittivity εᵣ′ of the dielectric layers 131 and 132 is a predetermined value (a set value).

The resonator according to Example 5 is the resonator 100C according to the fourth embodiment. Here, the cross-sectional shape of each of the first waveguide 110A and the second waveguide 120A according to Example 5 is a rectangle of which the lengths l₁ and l₂₁ of the long sides are 1.651 mm and the lengths l₁₂ and l₂₂ of the short sides are 0.825 mm. The diameters of the first communication hole 113 and the second communication hole 123 according to Example 5 are set to 0.7 mm.

The resonator according to Comparative Example 1 is the same as that of Example 5 except that the diameters of the first communication hole 113 and the second communication hole 123 are set to 0.8 mm.

The resonator according to Comparative Example 2 is the same as that of Example 5 except that the diameters of the first communication hole 113 and the second communication hole 123 are set to 0.88 mm.

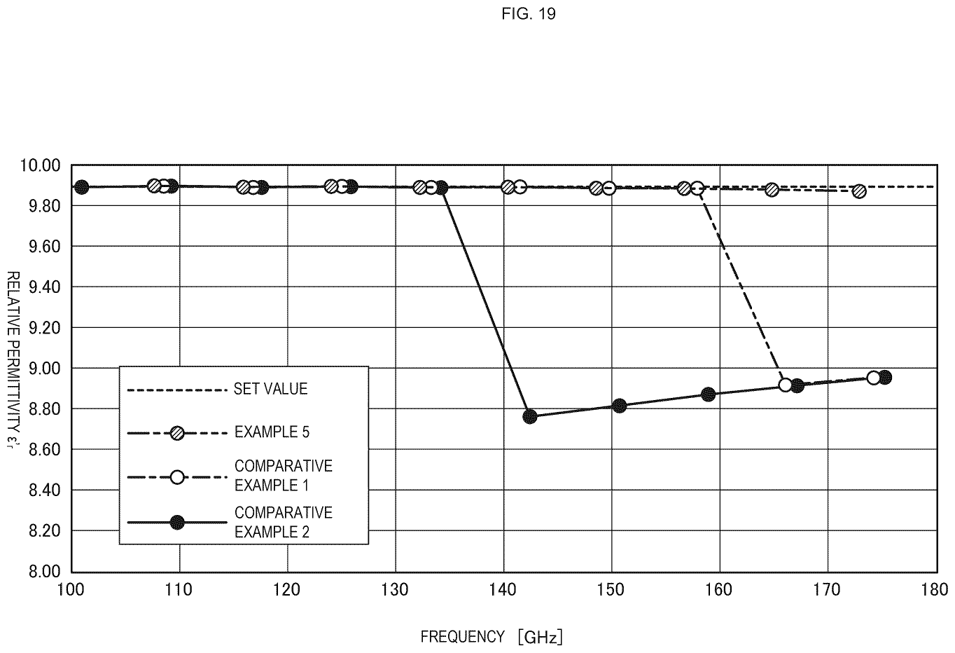

FIG. 19 is a diagram depicting a graph showing results of calculation of the dielectric characteristics according to Example 5, Comparative Example 1, and Comparative Example 2. In FIG. 19, plots of Example 5, Comparative Example 1, and Comparative Example 2 show values of the resonant frequency f₀ₘ₀ and values of the relative permittivity εᵣ′ calculated based on the resonant frequency f₀ₘ₀. Here, the set value shown in FIG. 19 is the set value of the relative permittivity εᵣ′ regarding each of the dielectric layers 131 and 132. In other words, the measurement of the dielectric characteristics can be carried out more accurately as the relative permittivity εᵣ′ calculated from the resonant frequency f₀ₘ₀ is closer to the set value.

As shown in FIG. 19, in Example 5, the relative permittivity εᵣ′ had a close value to the set value throughout the measurement frequency band. The resonator according to Example 5 therefore turns out to be capable of accurately measuring the dielectric characteristics throughout the measurement frequency band. This result is apparently due to the diameters of the first communication hole 113 and the second communication hole 123 according to Example 5 are 0.40 times as large as a free wavelength of the stop frequency (170 GHz) whereby neither the first communication hole 113 nor the second communication hole 123 transmitted the unnecessary wave as the waveguide throughout the measurement frequency band.

As shown in FIG. 19, in Comparative Example 1, the relative permittivity εᵣ′ was lower than the set value in a band equal to or above 160 GHz as compared to Example 5. The resonator according to Comparative Example 1 therefore turns out to be incapable of accurately measuring the dielectric characteristics in the band equal to or above 160 GHz. This result is apparently due to the diameters of the first communication hole 113 and the second communication hole 123 according to Example 5 are 0.45 times as large as the free wavelength of the stop frequency (170 GHz) whereby the first communication hole 113 and the second communication hole 123 transmitted the unnecessary wave as the waveguide in the band equal to or above 160 GHz.

As shown in FIG. 19, in Comparative Example 2, the relative permittivity εᵣ′ was lower than the set value in a band equal to or above 140 GHz as compared to Example 5. The resonator according to Comparative Example 1 therefore turns out to be incapable of accurately measuring the dielectric characteristics in the band equal to or above 160 GHz. This result is apparently due to the diameters of the first communication hole 113 and the second communication hole 123 according to Example 5 are 0.50 times as large as the free wavelength of the stop frequency (170 GHz) whereby the first communication hole 113 and the second communication hole 123 transmitted the unnecessary wave as the waveguide in the band equal to or above 140 GHz.

### (Third Test)

In a third test, simulation models of resonators according to Comparative Example 3, Comparative Example 4, and Example 6 were created while changing the diameters a of the first communication hole 113 and the second communication hole 123. In the third test, simulation of measurement values of the bandpass coefficient |S₂₁| in the measurement frequency band equal to or above 110 GHz and equal to or below 170 GHz was carried out by means of the electromagnetic field simulation using the simulation models of the resonators according to Comparative Example 3, Comparative Example 4, and Example 6.

The resonator according to Example 6 is the resonator 100C according to the fourth embodiment. Here, the cross-sectional shape of each of the first waveguide 110A and the second waveguide 120A according to Example 6 is a rectangle of which the lengths l₁ and l₂₁ of the long sides are 1.651 mm and the lengths l₁₂ and l₂₂ of the short sides are 0.825 mm. The diameters a of the first communication hole 113 and the second communication hole 123 according to Example 6 are set to 0.6 mm.

The resonator according to Comparative Example 3 is the same as that of Example 5 except that the diameters a of the first communication hole 113 and the second communication hole 123 are set to 0.5 mm.

The resonator according to Comparative Example 4 is the same as that of Example 5 except that the diameters a of the first communication hole 113 and the second communication hole 123 are set to 0.4 mm.

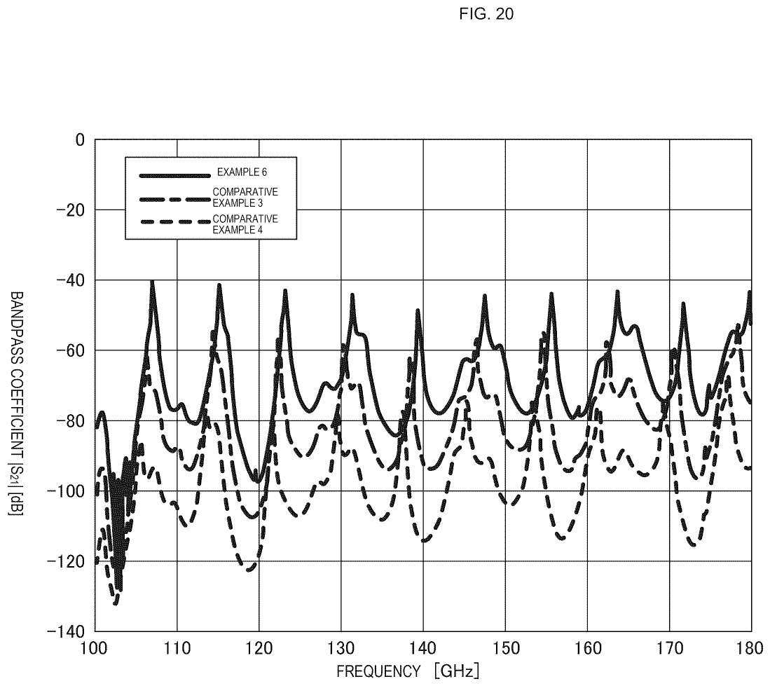

FIG. 20 is a diagram depicting a graph showing results of simulation according to Example 6, Comparative Example 3, and Comparative Example 4. As shown in FIG. 20, in Example 6, a magnitude of each peak in the resonant frequency is equal to or above −70 dB, and it turns out that the resonant wave having a sufficient intensity for the measurement is available. This result is apparently due to the diameters of the first communication hole 113 and the second communication hole 123 according to Example 5 are 0.22 times as large as the free wavelength of the start frequency (110 GHz) whereby the intensities of the evanescent waves caused to transition by using the first communication hole 113 and the second communication hole 123 are increased.

As shown in FIG. 20, in Comparative Example 3, a magnitude of each peak in the resonant frequency is around −70 dB, such that the resonant wave having the sufficient intensity for the measurement is not available. In this case, an influence of noise on the resonant wave is increased, resulting in inaccurate measurement of the resonant frequency or the 3-dB band width. This result is apparently due to the diameters of the first communication hole 113 and the second communication hole 123 according to Example 5 are 0.18 times as large as the free wavelength of the start frequency (110 GHz) whereby the intensities of the evanescent waves caused to transition by using the first communication hole 113 and the second communication hole 123 are decreased.

As shown in FIG. 20, in Comparative Example 4, a magnitude of each peak in the resonant frequency is below −70 dB, such that the resonant wave having the sufficient intensity for the measurement is not available. In this case, the influence of noise on the resonant wave is increased, resulting in inaccurate measurement of the resonant frequency or the 3-dB band width. This result is apparently due to the diameters of the first communication hole 113 and the second communication hole 123 according to Example 5 are 0.15 times as large as the free wavelength of the start frequency (110 GHz) whereby the intensities of the evanescent waves caused to transition by using the first communication hole 113 and the second communication hole 123 are decreased.

Note that the above-described embodiments are intended to facilitate the understanding of the present disclosure and are not intended to limit the interpretation of the present disclosure. The present disclosure can be changed/modified without departing from the gist thereof, and those equivalents are also encompassed by the present disclosure.

For example, the resonator may be provided according to a first modified example to be described below.

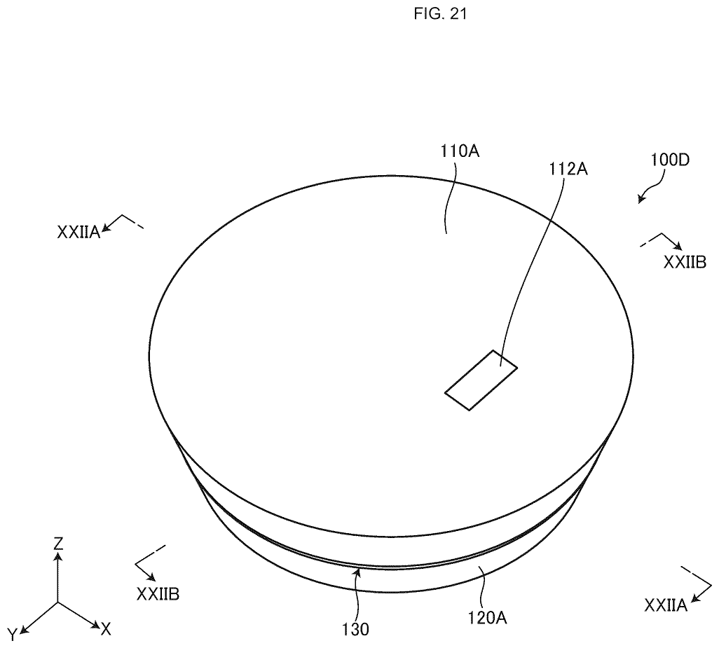

FIG. 21 is a perspective view of a resonator according to the first modified example. A resonator 100D according to the first modified example is different from the first embodiment in that the connecting portion is provided at a principal surface of the waveguide and each propagation path is provided with a bend. Now, the resonator 100D according to the first modified example will be described below. Note that the same structures as those of the first embodiment will be denoted by the same reference signs and explanations thereof will not be repeated.

As shown in FIG. 21, a first connecting portion 112A according to the first modified example is provided at a principal surface of a first waveguide 110B, i.e., a surface in the z direction of the first waveguide 110B which is a surface on an opposite side from the multilayer body 130 side. The first connecting portion 112A is formed into a frame-like member having a cavity that penetrates in the z direction.

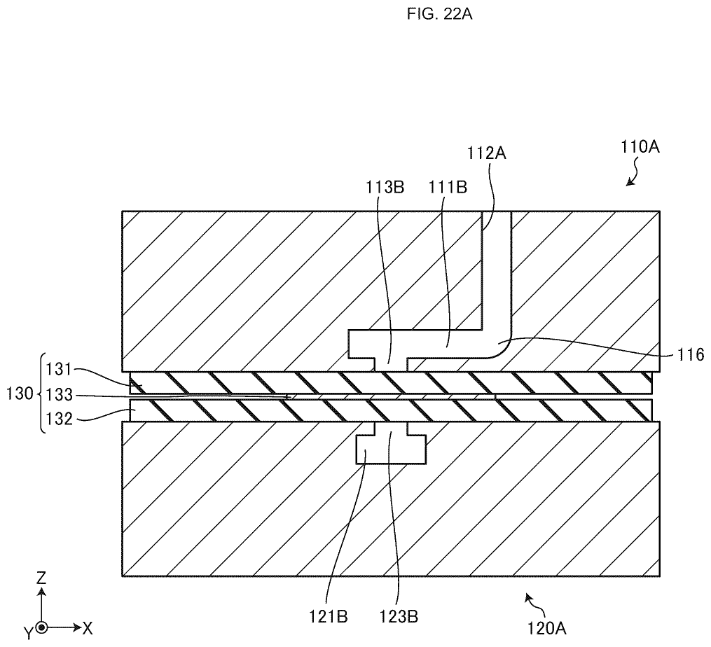

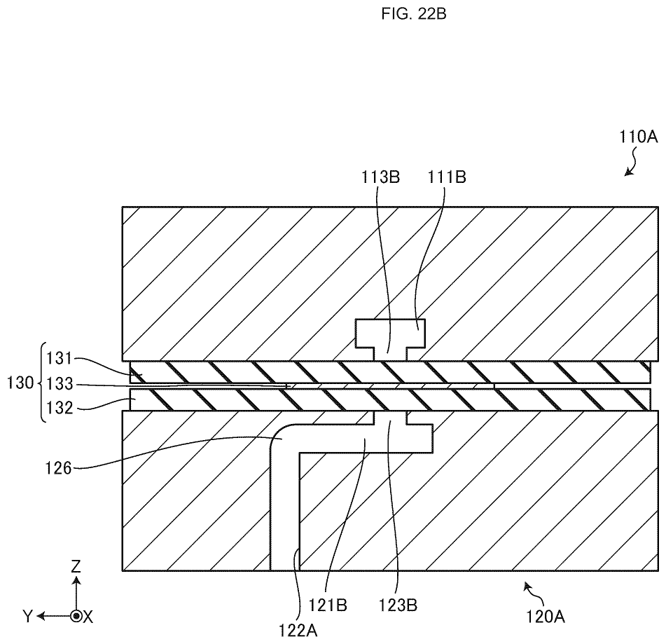

FIG. 22A is a cross-sectional view taken along line XXIIA-XXIIA in FIG. 21. As shown in FIG. 22A, a first propagation path 111B according to the first modified example includes a first bend 116 between the first connecting portion 112A and the first communication hole 113. Specifically, a shape of an inner wall of the first propagation path 111B has such a shape that changes a direction of the propagation path on the way, which represents a so-called curved waveguide. In the example of FIG. 22A, the shape of the inner wall of the first propagation path 111B is formed into an L-shape which proceeds from the first connecting portion 112A toward the multilayer body 130 in the z direction, then changes the direction at the first bend 116, and then proceeds toward the first communication hole 113 in the x direction until reaching the first communication hole 113. In the example of FIG. 22A, a shape of an inner wall of the first bend 116 is formed into a quadrant shape in plain view in the y direction. This configuration allows the occurrence of an unnecessary mode originating from the direction of propagation of the first propagation path 111B to be surpassed so that the occurrence of an unnecessary wave can be suppressed. Meanwhile, the input wave may be kept from being reflected from the inner wall of the first propagation path 111B and returning to the first connecting portion 112A side, so that attenuation of the output wave due to the reflected wave can be suppressed.

As with the first connecting portion 112A, a second connecting portion 122A according to the first modified example is provided at a principal surface of a second waveguide 120B, i.e., a surface in the z direction of the second waveguide 120B which is a surface on an opposite side from the multilayer body 130 side. The second connecting portion 122A is formed into a frame-like member having a cavity that penetrates in the z direction.

FIG. 22B is a cross-sectional view taken along line XXIIB-XXIIB in FIG. 21. As shown in FIG. 22B, a second propagation path 121B according to the first modified example includes a second bend 126 between the second connecting portion 122A and the second communication hole 123. Specifically, a shape of an inner wall of the second propagation path 121B has such a shape that changes a direction of the propagation path on the way, which represents a so-called curved waveguide. In the example of FIG. 22B, as with the first propagation path 111B, the shape of the inner wall of the second propagation path 121B is formed into an L-shape which proceeds from the second communication hole 123 toward the second connecting portion 122A in the y direction, then changes the direction at the second bend 126, and then proceeds in an opposite direction to the direction toward the multilayer body 130 in the z direction until reaching the second connecting portion 122A. In the example of FIG. 22A, a shape of an inner wall of the second bend 126 is formed into a quadrant shape in plan view in the x direction as with the first bend 116. In this way, an unnecessary mode originating from the direction of propagation of the first propagation path 111B may be kept from being propagated in the second propagation path 121B as well. Thus, the occurrence of an unnecessary wave can be suppressed.

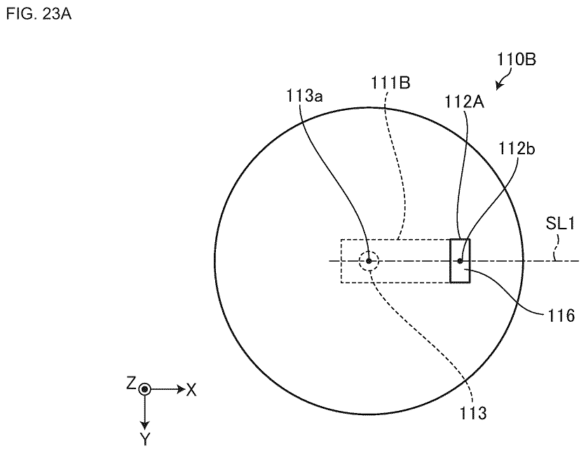

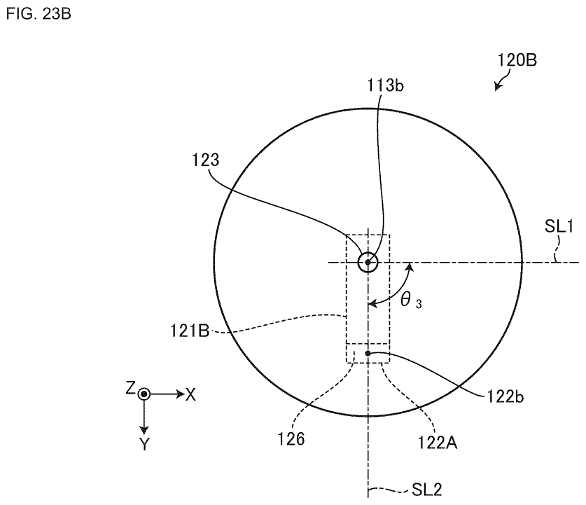

FIG. 23A is a plan view showing the first waveguide according to the first modified example. FIG. 23B is a plan view showing the second waveguide according to the first modified example. In the first modified example, the straight line SL1 that passes through the circular center 113a of the first communication hole 113 and the center 112b of the cavity of the first connecting portion 112A crosses the straight line SL2 that passes through the circular center 123a of the second communication hole 123 and the center 122b of the cavity of the second connecting portion 122A. In the example of FIG. 23B, the straight line SL2 that connects the circular center 123a of the second communication hole 123 to the center 122a of the cavity of the second connecting portion 122 is parallel to the y direction. Thus, an angle 83 formed between the straight line SL1 and the straight line SL2 is 90°. In this way, an unnecessary mode originating from the direction of propagation of the first propagation path 111B may be kept from being propagated in the second propagation path 121B as well. Thus, the occurrence of an unnecessary wave can be suppressed. Meanwhile, the input wave may be kept from being reflected from the inner wall of the first propagation path 111B and returning to the first connecting portion 112A side, so that attenuation of the output wave due to the reflected wave can be suppressed.

Concerning the description of the claims, the present disclosure can adopt the following aspects.

(1)

A resonator including:
a first waveguide having a plate shape and provided with a first propagation path;
a second waveguide having a plate shape and provided with a second propagation path, the second waveguide being opposed to the first waveguide in a first direction; and
a multilayer body including a circular conductor foil and two dielectric layers having a plate shape and sandwiching the circular conductor foil in the first direction, in which
the first waveguide has a first connecting portion at one end of the first propagation path,
the second waveguide has a second connecting portion at one end of the second propagation path,
the first waveguide has, on a second waveguide side, a first communication hole to connect the first propagation path with a space between the first waveguide and the second waveguide,
the second waveguide has, on a first waveguide side, a second communication hole to connect the second propagation path with the space between the first waveguide and the second waveguide,
the multilayer body is provided in the space between the first waveguide and the second waveguide,
in plan view in the first direction, the first communication hole overlaps the first propagation path and an external form of the first communication hole is located inside an inner wall of the first propagation path,
in plan view in the first direction, the second communication hole overlaps the second propagation path and an external form of the second communication hole is located inside an inner wall of the second propagation path, and
in plan view in the first direction, the first communication hole and the second communication hole overlap a circular center of the circular conductor foil.
   (2)

The resonator according to (1), in which
a cross-sectional shape of the inner wall of the first propagation path is a rectangle, and
a cross-sectional shape of the inner wall of the second propagation path is a rectangle.
   (3)

The resonator according to (1), in which a direction of propagation of the first propagation path is a different direction from a direction of propagation of the second propagation path in plan view in the first direction.

(4)

The resonator according to (1), in which
the first propagation path includes a first branched propagation path and a second branched propagation path between the first connecting portion and the first communication hole, and
a length along a direction of propagation of the first propagation path from the first connecting portion to the first communication hole is equal between a propagation path routed through the first branched propagation path and a propagation path routed through the second branched propagation path.
   (5)

The resonator according to (1) or (4), in which
the second propagation path includes a third branched propagation path and a fourth branched propagation path between the second communication hole and the second connecting portion, and
a length along a direction of propagation of the second propagation path from the second communication hole to the second connecting portion is equal between a propagation path routed through the third branched propagation path and a propagation path routed through the fourth branched propagation path.
   (6)

A dielectric characteristic measurement system including:
the resonator according to (1);
a transmission unit that transmits an input wave to the resonator;
a reception unit that receives an output wave from the resonator; and
an information processing unit that calculates dielectric characteristics of the dielectric layers.
   (7)

The dielectric characteristic measurement system according to (6), in which
the transmission unit sweeps the input wave in a measurement frequency band equal to or above a start frequency and equal to or below a stop frequency, and transmits the input wave,
a cutoff frequency in a basic mode of the first waveguide is equal to or below the start frequency,
a cutoff frequency in a secondary mode of the first waveguide is larger than the stop frequency,
a cutoff frequency in the basic mode of the second waveguide is equal to or below the start frequency, and
a cutoff frequency in the secondary mode of the second waveguide is larger than the stop frequency.
   (8)

The dielectric characteristic measurement system according to (7), in which
a length of an inner wall of the first communication hole in the first direction is equal to or below 0.4 times of a free space wavelength of an electromagnetic wave at the stop frequency, and
a length of an inner wall of the second communication hole in the first direction is equal to or below 0.4 times of the free space wavelength of the electromagnetic wave at the stop frequency.
   (9)

The dielectric characteristic measurement system according to (7), in which
the first communication hole and the second communication hole are circular in plan view in the first direction,
a diameter of the first communication hole in plan view in the first direction is equal to or above 0.2 times of a free space wavelength of an electromagnetic wave at the start frequency and equal to or below 0.4 times of a free space wavelength at the stop frequency, and
a diameter of the second communication hole in plan view in the first direction is equal to or above 0.2 times of the free space wavelength of the electromagnetic wave at the start frequency and equal to or below 0.4 times of the free space wavelength at the stop frequency.
   (10)

A dielectric characteristic measuring method including the steps of:
transmitting an input wave to the resonator according to (1);
receiving an output wave from the resonator; and
calculating dielectric characteristics of the dielectric layers.

### REFERENCE SIGNS LIST

1 dielectric characteristic measurement system
100, 100A, 100B, 100C, 100D resonator
110, 110A, 110B first waveguide
111, 111A, 111B first propagation path
112, 112A first connecting portion
112a, 112b center
113 first communication hole
113a circular center
114a first branched propagation path
114b second branched propagation path
115 first branch
116 first bend
120, 120A, 120B second waveguide
121, 121A, 121B second propagation path
122, 122A second connecting portion
122a, 122b center
123 second communication hole
123a circular center
124a third branched propagation path
124b fourth branched propagation path
125 second branch
126 second bend
130 multilayer body
131, 132 dielectric layer
133 circular conductor foil
20A, 20B converter
21A, 21B waveguide
22A, 22B flange
30 measurement apparatus
40 information processing apparatus
41 input unit
42 communication unit
43 storage unit
44 output unit
450 control unit
451 measurement control unit
452 dielectric characteristic calculation unit
SL1, SL2 straight line

1. A resonator comprising:
a first waveguide having a plate shape and provided with a first propagation path;
a second waveguide having a plate shape and provided with a second propagation path, the second waveguide being opposed to the first waveguide in a first direction; and
a multilayer body including a circular conductor foil and two dielectric layers having a plate shape, the two dielectric layers sandwiching the circular conductor foil in the first direction, wherein
the first waveguide has a first connecting portion at one end of the first propagation path,
the second waveguide has a second connecting portion at one end of the second propagation path,
the first waveguide has, on a second waveguide side, a first communication hole to connect the first propagation path with a space between the first waveguide and the second waveguide,
the second waveguide has, on a first waveguide side, a second communication hole to connect the second propagation path with the space between the first waveguide and the second waveguide,
the multilayer body is provided in the space between the first waveguide and the second waveguide,
in plan view in the first direction, the first communication hole overlaps the first propagation path and an external form of the first communication hole is located inside an inner wall of the first propagation path,
in plan view in the first direction, the second communication hole overlaps the second propagation path and an external form of the second communication hole is located inside an inner wall of the second propagation path, and
in plan view in the first direction, the first communication hole and the second communication hole overlap a center of the circular conductor foil.

2. The resonator according to claim 1, wherein
a cross-sectional shape of the inner wall of the first propagation path is a rectangle, and
a cross-sectional shape of the inner wall of the second propagation path is a rectangle.

3. The resonator according to claim 2, wherein
a length of a long side of the rectangle of the first propagation path is twice a length of a short side, and
a length of a long side of the rectangle of the second propagation path is twice a length of a short side.

4. The resonator according to claim 3, wherein
the short side of the first and second propagation paths extends in the first direction.

5. The resonator according to claim 1, wherein a direction of propagation of the first propagation path is a different direction from a direction of propagation of the second propagation path in plan view in the first direction.

6. The resonator according to claim 5, wherein the direction of propagation of the first propagation path is at 90° to the direction of propagation of the second propagation path in plan view in the first direction.

7. The resonator according to claim 1, wherein
the first propagation path includes a first branched propagation path and a second branched propagation path between the first connecting portion and the first communication hole, and
a length along a direction of propagation of the first propagation path from the first connecting portion to the first communication hole is equal between a propagation path routed through the first branched propagation path and a propagation path routed through the second branched propagation path.

8. The resonator according to claim 7, wherein
the second propagation path includes a third branched propagation path and a fourth branched propagation path between the second communication hole and the second connecting portion, and
a length along a direction of propagation of the second propagation path from the second communication hole to the second connecting portion is equal between a propagation path routed through the third branched propagation path and a propagation path routed through the fourth branched propagation path.

9. The resonator according to claim 1, wherein the first communication hole and the second communication hole have a same shape and size.

10. A dielectric characteristic measurement system comprising:
the resonator according to claim 1;
a transmission circuit configured to transmit an input wave to the resonator;
a reception circuit configured to receive an output wave from the resonator; and
an information processing circuit configured to calculate dielectric characteristics of the dielectric layers.

11. The dielectric characteristic measurement system according to claim 10, wherein
the transmission circuit is configured to sweep the input wave in a measurement frequency band equal to or above a start frequency and equal to or below a stop frequency, and transmits the input wave,
a cutoff frequency in a basic mode of the first waveguide is equal to or below the start frequency,
a cutoff frequency in a secondary mode of the first waveguide is larger than the stop frequency,
a cutoff frequency in the basic mode of the second waveguide is equal to or below the start frequency, and
a cutoff frequency in the secondary mode of the second waveguide is larger than the stop frequency.

12. The dielectric characteristic measurement system according to claim 11, wherein
a length of an inner wall of the first communication hole in the first direction is equal to or below 0.4 times of a free space wavelength of an electromagnetic wave at the stop frequency, and
a length of an inner wall of the second communication hole in the first direction is equal to or below 0.4 times of the free space wavelength of the electromagnetic wave at the stop frequency.

13. The dielectric characteristic measurement system according to claim 12, wherein
the first communication hole and the second communication hole are circular in plan view in the first direction,
a diameter of the first communication hole in plan view in the first direction is equal to or above 0.2 times of a free space wavelength of an electromagnetic wave at the start frequency and equal to or below 0.4 times of a free space wavelength at the stop frequency, and
a diameter of the second communication hole in plan view in the first direction is equal to or above 0.2 times of the free space wavelength of the electromagnetic wave at the start frequency and equal to or below 0.4 times of the free space wavelength at the stop frequency.

14. The dielectric characteristic measurement system according to claim 13, wherein
a length of the inner wall of the first communication hole in the first direction is larger than a skin thickness of a material of the first waveguide at a start frequency of a measurement frequency band, and
a length of the inner wall of the second communication hole in the first direction is larger than a skin thickness of a material of the second waveguide at the start frequency.

15. The dielectric characteristic measurement system according to claim 11, wherein
the first communication hole and the second communication hole are circular in plan view in the first direction,
a diameter of the first communication hole in plan view in the first direction is equal to or above 0.2 times of a free space wavelength of an electromagnetic wave at the start frequency and equal to or below 0.4 times of a free space wavelength at the stop frequency, and
a diameter of the second communication hole in plan view in the first direction is equal to or above 0.2 times of the free space wavelength of the electromagnetic wave at the start frequency and equal to or below 0.4 times of the free space wavelength at the stop frequency.

16. The dielectric characteristic measurement system according to claim 11, wherein
a length of the inner wall of the first communication hole in the first direction is larger than a skin thickness of a material of the first waveguide at the start frequency, and
a length of the inner wall of the second communication hole in the first direction is larger than a skin thickness of a material of the second waveguide at the start frequency.

17. The dielectric characteristic measurement system according to claim 10, wherein a radius of the circular conductor foil is selected based on a desired resonant frequency range for dielectric characteristic measurement.

18. A dielectric characteristic measuring method comprising:
transmitting an input wave to the resonator according to claim 1;
receiving an output wave from the resonator; and
calculating dielectric characteristics of the dielectric layers.
